(19) United States
(12) Patent Application Publication
(10) Pub. No.: US 2026/0120786 A1
(43) Pub. Date: Apr. 30, 2026

(54) BLOCK TO BLOCK TESTING WITH SINGLE SET OF CGI LINES

(71) Applicant: Sandisk Technologies, Inc., Milpitas, CA (US)

(72) Inventors: Hiroki Yabe, Yokohama (JP); Kyosuke Matsumoto, Sagamihara (JP); Yasuyuki Fujihara, Fujisawa (JP); Takuya Ariki, Yokohama (JP)

(73) Assignee: Sandisk Technologies, Inc., Milpitas, CA (US)

(21) Appl. No.: 18/933,006

(22) Filed: Oct. 31, 2024

(51) Int. Cl. G11C 29/12; G11C 16/04; G11C 16/08

(52) U.S. Cl. CPC G11C 29/12005; G11C 16/0483; G11C 16/08; G11C 2029/1202

(57) ABSTRACT

Technology for testing non-volatile memory. The memory system uses a single set of “n” common global interconnect (CGI) lines to test blocks of memory cells, with each block having “n” word lines. There is a set “n” word line switches associated with each block of memory cells, with each block having n word lines. Each CGI line connects to one word line switch in each set of word line switches. However, the mapping of the CGI lines to word line switches differs between the odd blocks and the even blocks. A single set of CGI lines to be used for tests involving adjacent blocks such as leakage current tests and stress tests. Moreover, this single set of CGI lines may also be used for normal memory operations such as read, write, and erase.

### BACKGROUND

The present disclosure relates to technology for non-volatile storage.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery).

A memory structure in the memory system typically contains many memory cells and various control lines. Herein, a memory system that uses non-volatile memory for storage may be referred to as a storage system. The memory structure may be three-dimensional (3D). One type of 3D structure has non-volatile memory cells arranged as vertical NAND strings. The 3D memory structure may be arranged into units that are commonly referred to as blocks. For example, a block in a NAND memory system contains many NAND strings. A NAND string contains memory cell transistors connected in series, a drain side select gate at one end, and a source side select gate at the other end. Each NAND string is associated with a bit line. The block typically has many word lines that provide voltages to the control gates of the memory cell transistors. In some architectures, each word line connects to the control gate of one memory cell on each respective NAND string in the physical block. The memory system may have a large number of blocks, with each block containing NAND strings and associated word lines. Each block could have over one hundred word lines and there may be thousands of blocks. Therefore, there may be a very large number of word lines in the memory system.

There may be defects such as short circuits between word lines in adjacent blocks of memory cells. The memory system may perform tests to detect such short circuits and/or stress the memory blocks. It is desirable to reduce the amount and complexity of the circuitry that is used to perform such tests.

The memory system typically has circuitry that provides voltages to word lines. Such circuitry may include word line drivers, word line decoders, and word line switches (also referred to as transfer gates). Typically there are conductive lines that connect the word line drivers to the word line switches.

FIG. 1 is a schematic diagram of conventional circuitry that may be used to apply voltages to word lines. The circuitry can be used during normal memory operations such as read, write, and erase, as well as for testing the memory system. FIG. 1 shows a simplified example of four blocks (BLK0, BLK1, BLK2, BLK3), each with eight word lines (WL0-WL7). Typically each block will contain more than eight word lines, as well as other control lines such as select lines. There is a set of word line switches associated with each block in order to provide voltages to the word lines in that block. Word line switches 12 are associated with BLK0, word line switches 14 are associated with BLK1, word line switches 16 are associated with BLK2, and word line switches 18 are associated with BLK3. Each word line switch is connected to a common global interconnect (CGI) line in order for the CGI line to provide a voltage to the word line switch. The control gates of the word line switches may be driven with decode signals to selectively pass the voltage from the CGI line to the word line driven by the word line switch.

Significantly, this conventional design has two or more sets of CGI lines. The first set of CGI lines is connected to and provides voltages to the word line switches 12, 16 associated with the even blocks (BLK0, BLK2). The second set of CGI lines is connected to and provides voltages to the word line switches 14, 18 associated with the odd blocks (BLK1, BLK3). In this simplified example each set of CGI lines has eight lines (i.e., N=8); however, typically there will be many more word line switches per block hence many more CGI lines in each set.

Having two sets of CGI lines allows the memory system to select two adjacent blocks and apply different voltages to word lines in one block than the other block for testing purposes. For example, the memory system could apply a high voltage to WL0 in BLK0 (using a CGI in the 1^{st} set of CGIs) while applying a low voltage to WL0 in BLK1 (using a CGI in the 2^{nd} set of CGIs). This high voltage to low voltage may be used to test for a leakage current between WL0 in BLK0 and WL0 in BLK1.

However, this conventional architecture and method requires two sets of CGI lines. A block of, for example, NAND memory cells may have hundreds of word lines. Therefore, each set of CGI lines may have hundreds of lines. Doubling the number of CGI lines (i.e., two sets) results in a very large number of CGI lines. The large number of CGI lines not only occupies considerable chip space, but places considerable burden with routing this many CGI lines.

### BRIEF DESCRIPTION OF THE DRAWINGS

Like-numbered elements refer to common components in the different FIGURES.

FIG. 1 is a schematic diagram of conventional circuitry that may be used to apply voltages to word lines.

FIG. 2A is a block diagram depicting one embodiment of a memory system.

FIG. 2B is a block diagram of one embodiment of a memory die.

FIG. 2C is a block diagram of one embodiment of an integrated memory assembly.

FIGS. 3A and 3B depict different embodiments of integrated memory assemblies.

FIG. 3C is a block diagram depicting one embodiment of a portion of column control circuitry that contains a number of read/write circuits.

FIG. 4 is a perspective view of a portion of one example embodiment of a monolithic three dimensional memory structure.

FIG. 4A is a block diagram of one embodiment of a memory structure having two planes.

FIG. 4B is a block diagram depicting a top view of a portion of block of memory cells showing an array region.

FIG. 4C depicts an example of a stack showing a cross-sectional view along line AA of FIG. 4B.

FIG. 4D depicts a view of the region 445 of FIG. 4C.

FIG. 4E is a schematic diagram of a portion of one embodiment of a block, depicting several NAND strings.

FIG. 5 depicts an embodiment of circuitry for providing voltage to blocks of memory cells.

FIG. 6 depicts an example of how an embodiment of the circuitry in FIG. 5 may be used to perform a current leakage test to determine whether there may be a short circuit between word lines in two adjacent blocks.

FIG. 7 depicts another example of how an embodiment of the circuitry in FIG. 5 may be used to perform a current leakage test.

FIG. 8 shows further details of an embodiment of circuitry for providing voltages to word lines.

FIG. 9 shows a table of an example mapping of CGI lines to word lines in even and odd blocks.

FIG. 10 shows an example of voltages that may be applied to an even block and an odd block during a stress test.

FIG. 11 is a table depicting an example of mapping a set of CGI lines to word lines in even and odd blocks for a stress test.

FIG. 12 shows another example of voltages that may be applied to an even block and an odd block during a stress test.

FIG. 13 is a table depicting an example of mapping a set of CGI lines to word lines in even and odd blocks for a stress test.

FIG. 14 shows details two WLSW transistors.

FIG. 15A shows a cross sectional view of an even block having word line contacts.

FIG. 15B shows a cross sectional view of an odd block having word line contacts.

FIG. 16 shows a WLSW transistors that may be used to provide voltages for word line contacts in the even block in FIG. 15A and the odd block in FIG. 15B.

FIG. 17A shows a cross sectional view of an even block having word line contacts.

FIG. 17B shows a cross sectional view of an odd block having word line contacts.

FIG. 18 shows a WLSW transistors that may be used to provide voltages for word line contacts in the even block in FIG. 17A and the odd block in FIG. 17B.

FIG. 19 depicts an embodiment of a physical layout of WLSW transistors having three rows of WLSW transistors per two blocks of memory cells.

FIG. 20 shows one example of how the word lines may be placed into nine groups (A-I).

FIG. 21 depicts one embodiment of details of the circuitry for swapping of the word lines groups in connection with the CGI lines.

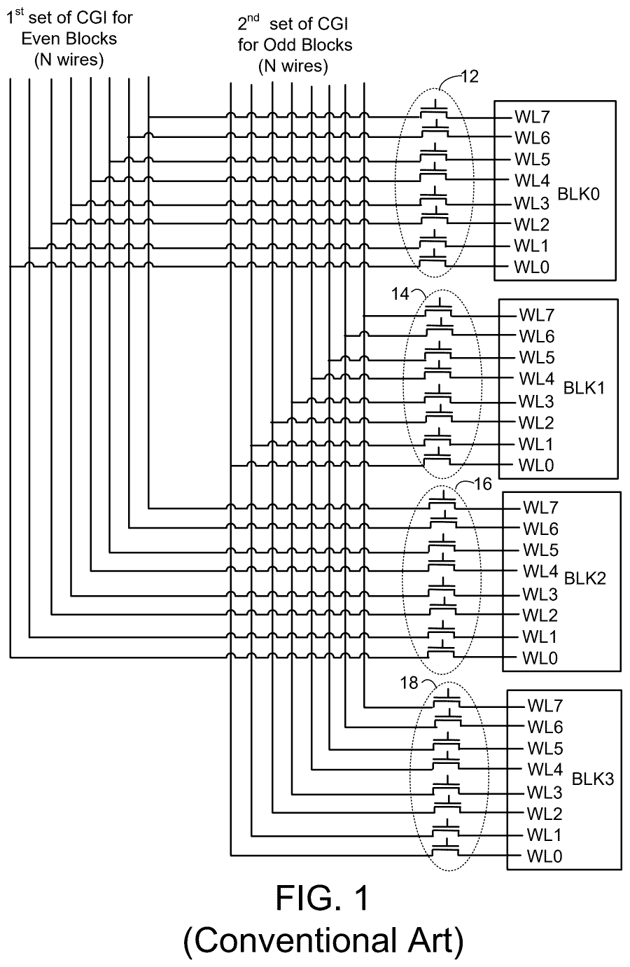

### DETAILED DESCRIPTION

Technology is disclosed for circuitry and methods for testing non-volatile memory. The memory system uses a single set of “n” common global interconnect (CGI) lines to test blocks of memory cells, with each block having “n” word lines. There is a set “n” word line switches associated with each block of memory cells, with each block having n word lines. The blocks may be referred to as even numbered blocks and odd numbered blocks based on a numbering scheme (e.g., addresses) that is based on the blocks' locations. The even blocks alternate with the odd blocks based on the blocks' locations. Thus, by the definition used herein even blocks are adjacent to odd blocks. The word lines may be numbered (or addressed) based on their physical location in the block. Likewise, the word line switches may be numbered based on the word line that the word line switch drives. Each CGI line connects to one word line switch in each set of word line switches. However, the mapping of the CGI lines to word line switches differs between the odd blocks and the even blocks. For example, each CGI line may be connected to a different numbered word line switch in the word line switches that drive the even blocks than the word line switches that drive the odd blocks. As another example, a word line switch that drives a specific numbered word line in an even block may be connected to a different CGI line than a word line switch that drives that specific numbered word line in an odd block, which allows these two different CGI lines to provide different voltages to the same numbered word line in adjacent blocks. The foregoing allows a single set of CGI lines to be used for tests involving adjacent blocks, such as leakage current tests and stress tests. Moreover, this single set of CGI lines may also be used for normal memory operations such as read, write, and erase.

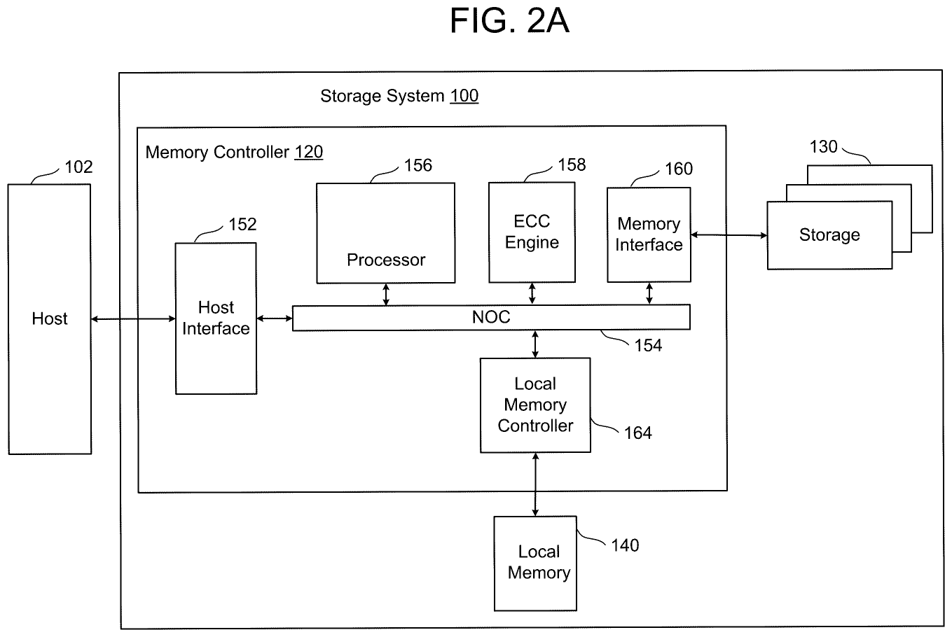

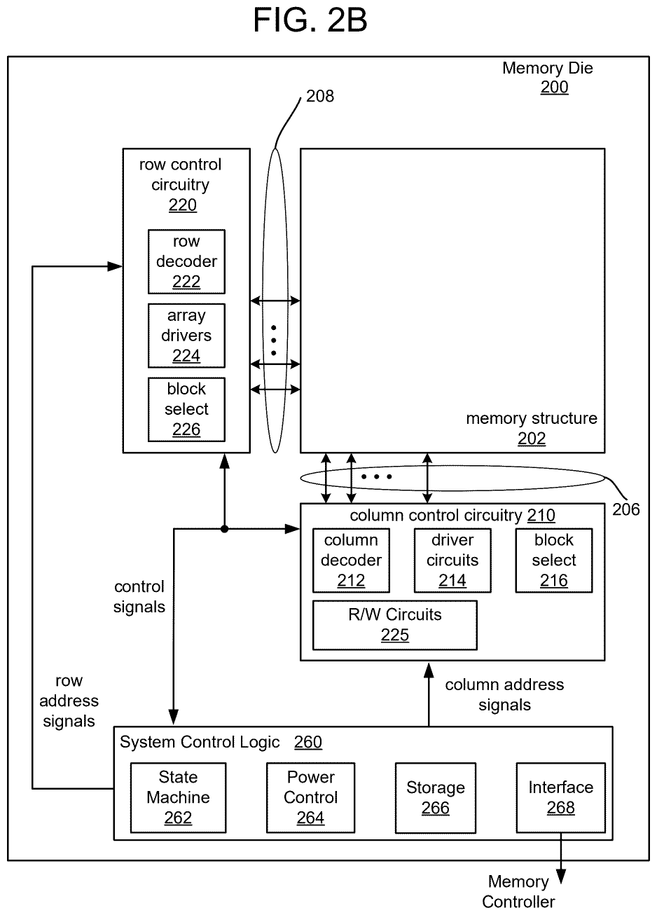

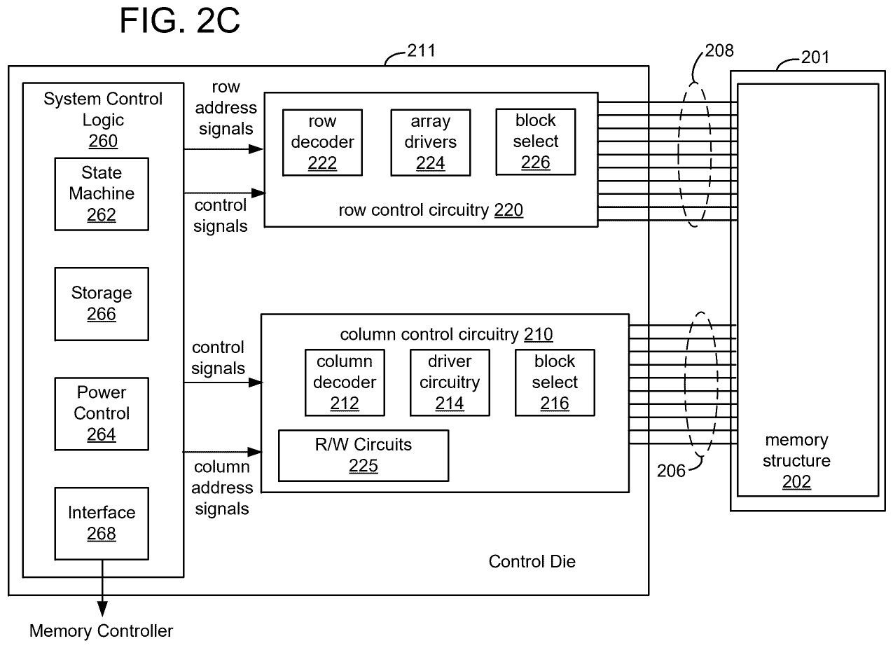

FIG. 2A is a block diagram of one embodiment of a memory system 100 that implements the technology described herein. In one embodiment, memory system 100 is a solid state drive (“SSD”). Memory system 100 can also be a memory card, USB drive or other type of memory system. The proposed technology is not limited to any one type of memory system. Memory system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, memory system 100. In other embodiments, memory system 100 is embedded within host 102.

The components of memory system 100 depicted in FIG. 2A are electrical circuits. Memory system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOCs can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations such as programming, erasing, reading, and memory management processes. In one embodiment, processor 156 is programmed by firmware. In other embodiments, processor 156 is a custom and dedicated hardware circuit without any software. Processor 156 may also implement a translation module, as a software/firmware process or as a dedicated hardware circuit. In many systems, the non-volatile memory is addressed internally to the memory system using physical addresses associated with the one or more memory die. However, the host system will use logical addresses to address the various memory locations. This enables the host to assign data to consecutive logical addresses, while the memory system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a memory system is so large that the local memory 140 cannot hold all of the L2P tables. In such a case, the entire set of L2P tables are stored in a storage 130 and a subset of the L2P tables are cached (L2P cache) in the local high speed memory 140.

Memory interface 160 communicates with non-volatile storage 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

In one embodiment, non-volatile storage 130 comprises one or more memory dies. FIG. 2B is a functional block diagram of one embodiment of a memory die 200 that comprises non-volatile storage 130. Each of the one or more memory dies of non-volatile storage 130 can be implemented as memory die 200 of FIG. 2B. The components depicted in FIG. 2B are electrical circuits. Memory die 200 includes a memory structure 202 (e.g., memory array) that can comprise non-volatile memory cells (also referred to as non-volatile storage cells), as described in more detail below.

The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic circuit 260, and typically may include such circuits as row decoders 222, array drivers 224, and block select circuitry 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only single block is shown for structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuitry 216, as well as read/write circuitry, and I/O multiplexers. The system control logic 260, column control circuitry 210, and/or row control circuitry 220 are configured to control memory operations such as open block reads at the die level.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2B can be grouped into two parts: (1) memory structure 202 and (2) peripheral circuitry, which includes all of the other components depicted in FIG. 2B. An important characteristic of a memory circuit is its capacity, which can be increased by increasing the area of the memory die of memory system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the memory system 100 is the amount of area to devote to the memory structure 202 and the amount of area to devote to the peripheral circuitry.

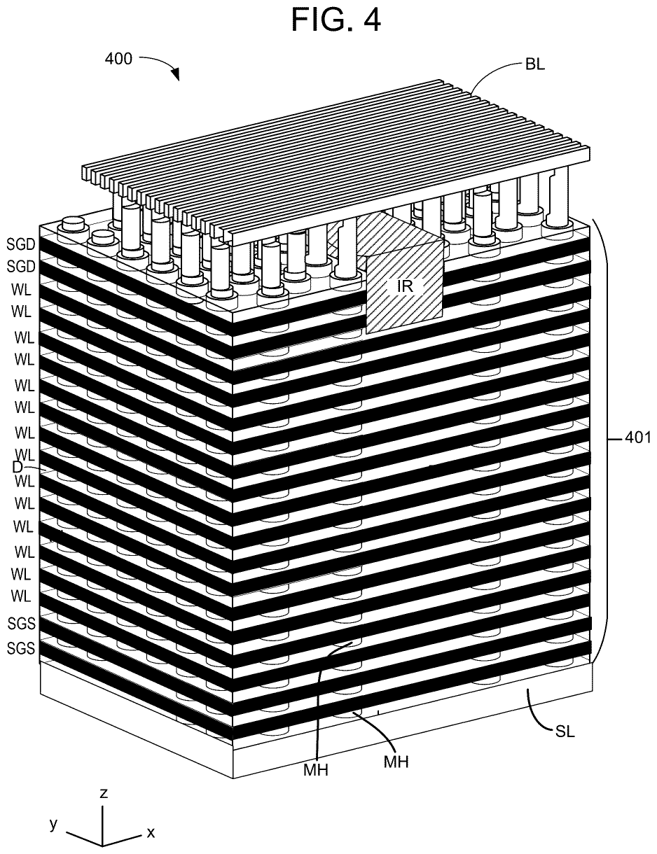

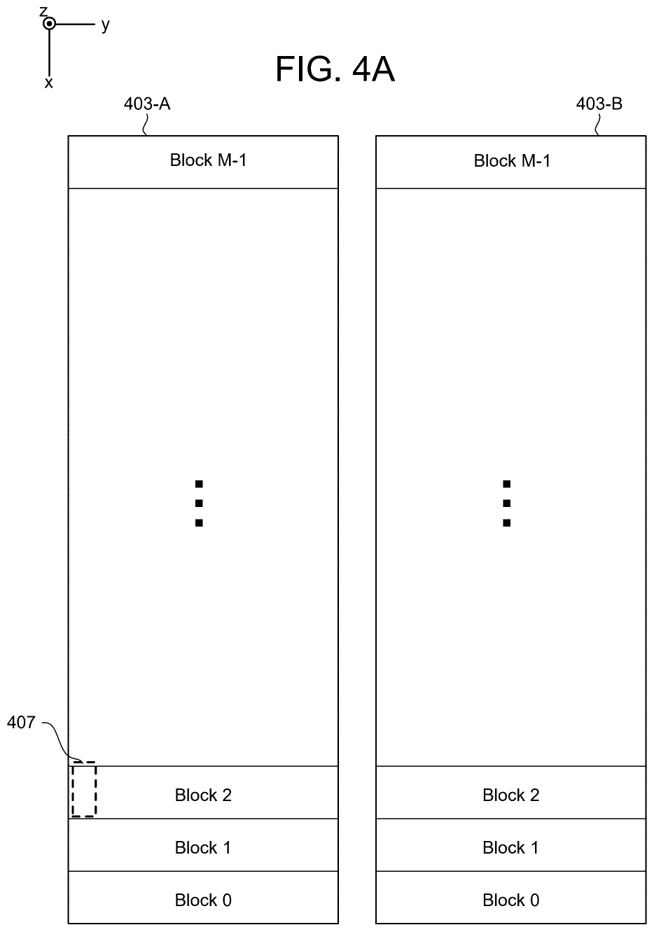

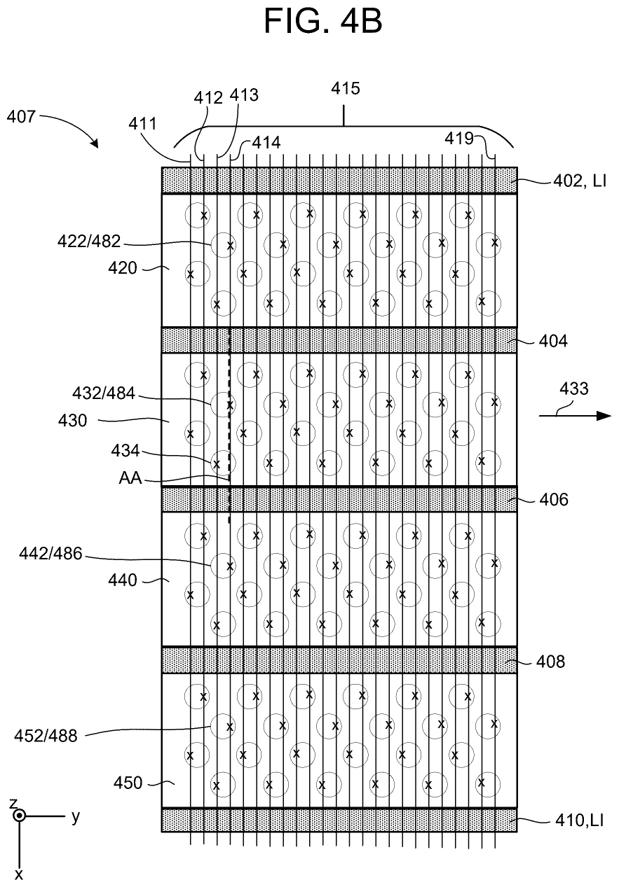

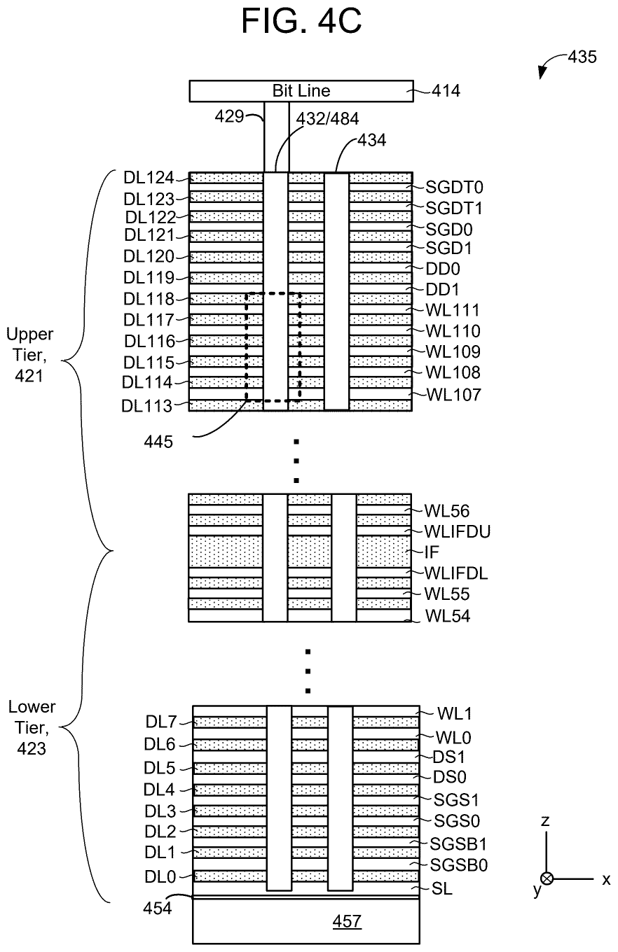

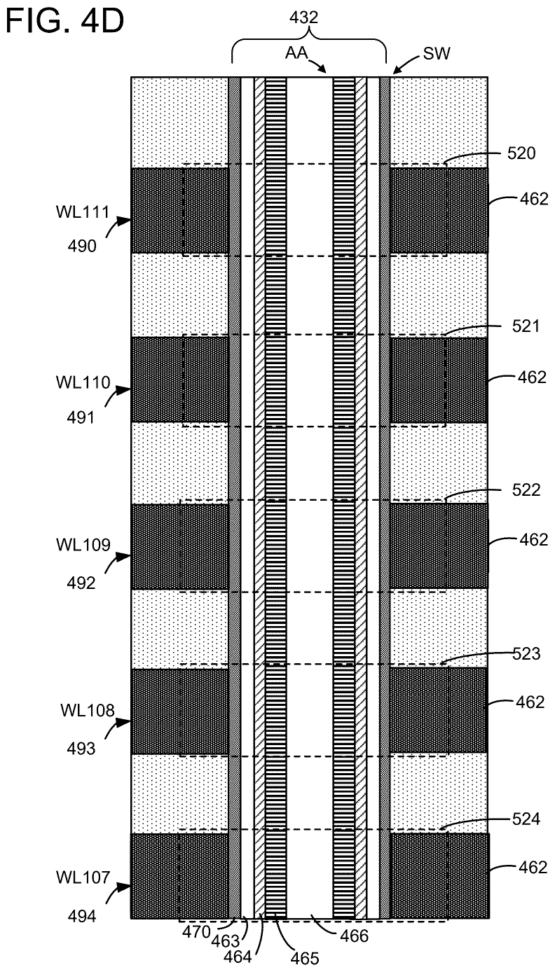

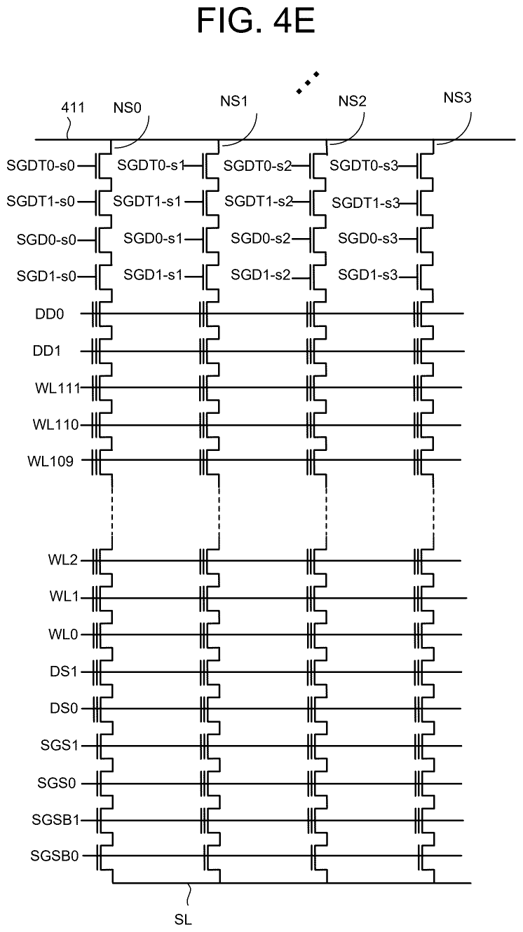

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures (see, for example, FIG. 4) in particular may benefit from specialized processing operations.

To improve upon these limitations, embodiments described below can separate the elements of FIG. 2B onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more dies, such as two memory dies and one control die, for example.

FIG. 2C shows an alternative arrangement to that of FIG. 2B which may be implemented using wafer-to-wafer bonding to provide a bonded die pair. FIG. 2C depicts a functional block diagram of one embodiment of an integrated memory assembly 207. One or more integrated memory assemblies 207 may be used to implement the non-volatile storage 130 of memory system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2C shows an example of the peripheral circuitry, including control circuits, formed in a peripheral circuit or control die 211 coupled to memory structure 202 formed in memory structure die 201. Common components are labelled similarly to FIG. 2B. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2C shows column control circuitry 210 including read/write circuits 225 on the control die 211 coupled to memory structure 202 on the memory structure die 201 through electrical paths 206. For example, electrical paths 206 may provide electrical connection between column decoder 212, driver circuitry 214, and block select 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select 226 are coupled to memory structure 202 through electrical paths 208. Each electrical path 208 may correspond to a word line, dummy word line, or select gate line. Additional electrical paths may also be provided between control die 211 and memory structure die 201.

For purposes of this document, the phrases “a control circuit” or “one or more control circuits” can include, but is not limited to, any one of or any combination of memory controller 120, all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit. For purposes of this document, the term “apparatus” can include, but is not limited to, one or more of, memory system 100, storage 130, memory die 200, integrated memory assembly 207, and/or control die 211.

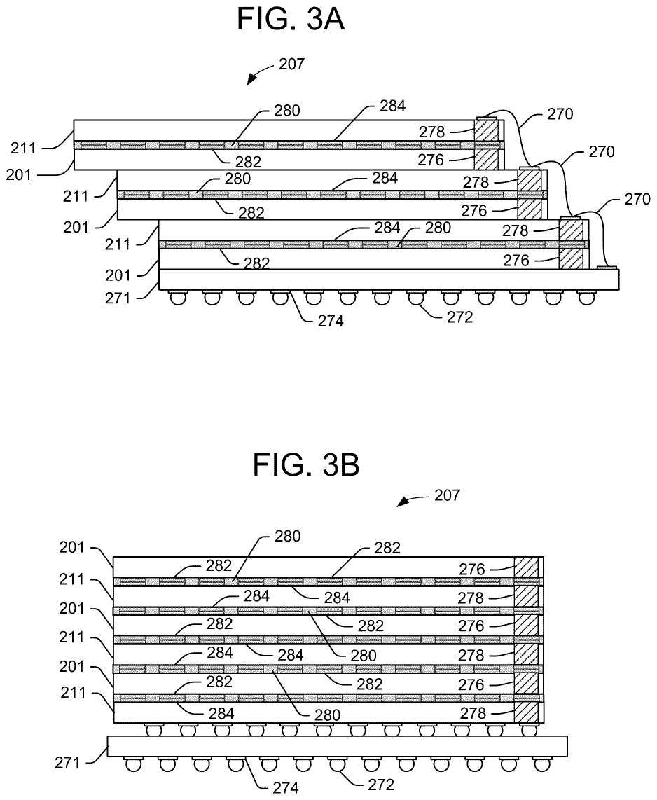

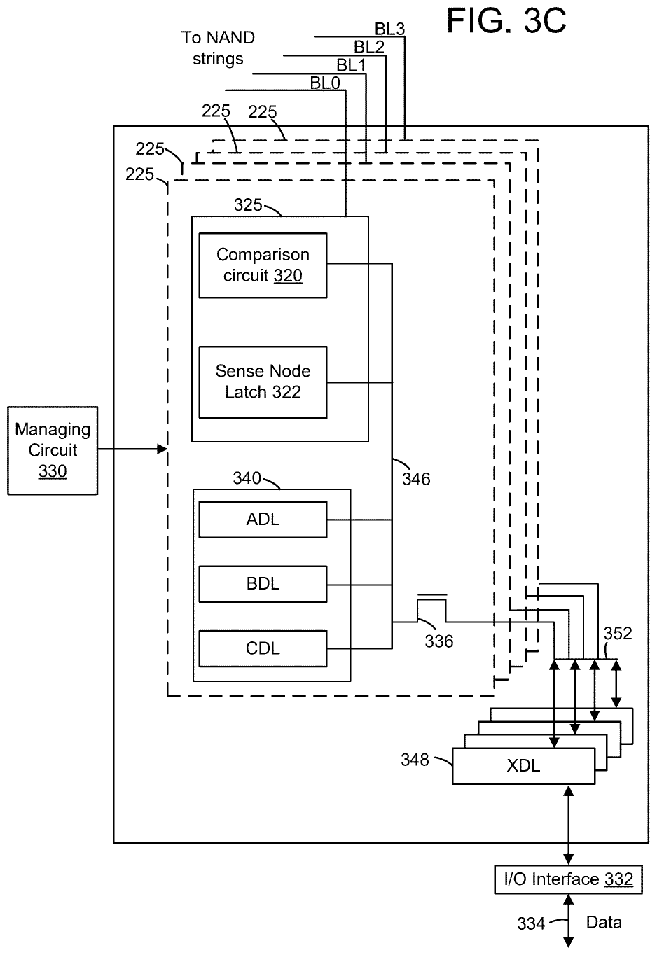

In some embodiments, there is more than one control die 211 and more than one memory structure die 201 in an integrated memory assembly 207. In some embodiments, the integrated memory assembly 207 includes a stack of multiple control dies 211 and multiple memory structure dies 201. FIG. 3A depicts a side view of an embodiment of an integrated memory assembly 207 stacked on a substrate 271 (e.g., a stack comprising control die 211 and memory structure die). The integrated memory assembly 207 has three control dies 211 and three memory structure dies 201. In some embodiments, there are more than three memory structure dies 201 and more than three control dies 211. In FIG. 3A there are an equal number of memory structure dies 201 and control dies 211; however, in one embodiment, there are more memory structure dies 201 than control dies 211. For example, one control die 211 could control multiple memory structure dies 201.

Each control die 211 is affixed (e.g., bonded) to at least one of the memory structure die 201. Some of the bond pads 282/284 are depicted. There may be many more bond pads. A space between two die 201, 211 that are bonded together is filled with a solid layer 280, which may be formed from epoxy or other resin or polymer. This solid layer 280 protects the electrical connections between the die 201, 211, and further secures the die together. Various materials may be used as solid layer 280.

The integrated memory assembly 207 may for example be stacked with a stepped offset, leaving the bond pads at each level uncovered and accessible from above. Wire bonds 270 connected to the bond pads connect the control die 211 to the substrate 271. A number of such wire bonds may be formed across the width of each control die 211 (i.e., into the page of FIG. 3A).

A memory die through silicon via (TSV) 276 may be used to route signals through a memory structure die 201. A control die through silicon via (TSV) 278 may be used to route signals through a control die 211. The TSVs 276, 278 may be formed before, during or after formation of the integrated circuits in the semiconductor dies 201, 211. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 3B depicts a side view of another embodiment of an integrated memory assembly 207 stacked on a substrate 271. The integrated memory assembly 207 of FIG. 3B has three control dies 211 and three memory structure dies 201. In some embodiments, there are many more than three memory structure dies 201 and many more than three control dies 211. In this example, each control die 211 is bonded to at least one memory structure die 201. Optionally, a control die 211 may be bonded to two or more memory structure dies 201.

Some of the bond pads 282, 284 are depicted. There may be many more bond pads. A space between two dies 201, 211 that are bonded together is filled with a solid layer 280, which may be formed from epoxy or other resin or polymer. In contrast to the example in FIG. 3A, the integrated memory assembly 207 in FIG. 3B does not have a stepped offset. A memory die through silicon via (TSV) 276 may be used to route signals through a memory structure die 201. A control die through silicon via (TSV) 278 may be used to route signals through a control die 211.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 211 and the memory structure die 201 may be bonded together. Bond pads on each die 201, 211 may be used to bond the two die together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor dies together. The size of, and pitch between, bond pads may be further reduced by providing a film layer on the surfaces of the semiconductor die including the bond pads. The film layer is provided around the bond pads. When the die are brought together, the bond pads may bond to each other, and the film layers on the respective die may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on surface of the dies 201, 211. Where no such film is initially provided, a space between the die may be under filled with an epoxy or other resin or polymer. The under-fill material may be applied as a liquid which then hardens into a solid layer. This under-fill step protects the electrical connections between the dies 201, 211, and further secures the die together. Various materials may be used as under-fill material.

FIG. 3C is a block diagram depicting one embodiment of a portion of column control circuitry 210 that contains a number of read/write circuits 225. Each read/write circuit 225 is partitioned into a sense amplifier 325 and data latches 340. A managing circuit 330 controls the read/write circuits 225. The managing circuit 330 may communicate with state machine 262. In one embodiment, each sense amplifier 325 is connected to a respective bit line. Each bit line may be connected, at one point in time, to one of a large number of different NAND strings. A select gate on the NAND string may be used to connect the NAND string channel to the bit line.

Each sense amplifier 325 operates to provide voltages to one of the bit lines (see BL0, BL1, BL2, BL3) during program, verify, erase, and read operations. Sense amplifiers are also used to sense the condition (e.g., data state) of a memory cell in a NAND string connected to the bit line that connects to the respective sense amplifier. The following will discuss use of the sense amplifier 325 to sense a condition (e.g., data state) of a memory cell.

Each sense amplifier 325 may have a sense node. During sensing, a sense node is charged up to an initial voltage, Vsense_init, such as 3V. The sense node is then connected to the bit line for a sensing time, and an amount of decay of the sense node is used to determine whether a memory cell is in a conductive or non-conductive state. The amount of decay of the sense node also indicates whether a current Icell in the memory cell exceeds a reference current, Iref. A larger decay corresponds to a larger current. If Icell<=Iref, the memory cell is in a non-conductive state and if Icell>Iref, the memory cell is in a conductive state. In an embodiment, the sense node has a capacitor that is pre-charged and then discharged for the sensing time.

In particular, the comparison circuit 320 determines the amount of decay by comparing the sense node voltage to a trip voltage after the sensing time. If the sense node voltage decays below the trip voltage, Vtrip, the memory cell is in a conductive state and its Vth is at or below the verify voltage. If the sense node voltage does not decay below Vtrip, the memory cell is in a non-conductive state and its Vth is above the program verify voltage. A sense node latch 322 is set to 0 or 1, for example, by the comparison circuit 320 based on whether the memory cell is in a conductive or non-conductive state, respectively. The bit in the sense node latch 322 can also be used in a lockout scan to decide whether to set a bit line voltage to an inhibit or a program enable level in a next program loop. The bit in the sense node latch 322 can also be used in a lockout mode to decide whether to set a bit line voltage to a sense voltage or a lockout voltage in a read operation.

The data latches 340 are coupled to the sense amplifier 325 by a local data bus 346. The data latches 340 include three latches (ADL, BDL, CDL) for each sense amplifier 325 in this example. More or fewer than three latches may be included in the data latches 340. In one embodiment, for programming each data latch 340 is used to store one bit to be stored into a memory cell and for reading each data latch 340 is used to store one bit read from a memory cell. In a three bit per memory cell embodiment, ADL stores a bit for a lower page of data, BDL stores a bit for a middle page of data, CDL stores a bit for an upper page of data. Each read/write circuit 225 is connected to an XDL latch 348 by way of an XDL bus 352. In this example, transistor 336 connects local data bus 346 to XDL bus 352. An I/O interface 332 is connected to the XDL latches 348. The XDL latch 348 associated with a particular read/write circuit 225 serves as an interface latch for storing/latching data from the memory controller.

Managing circuit 330 performs computations, such as to determine the data stored in the sensed memory cell and store the determined data in the set of data latches. Each set of data latches 340 is used to store data bits determined by managing circuit 330 during a read operation, and to store data bits imported from the data bus 334 during a program operation which represent write data meant to be programmed into the memory. I/O interface 332 provides an interface between XDL latches 348 and the data bus 334.

During reading, the operation of the system is under the control of state machine 262 that controls the supply of different control gate voltages to the addressed memory cell. As it steps through the various predefined control gate voltages corresponding to the various memory states supported by the memory, the sense circuit may trip at one of these voltages and a corresponding output will be provided from the sense amplifier to managing circuit 330. At that point, managing circuit 330 determines the resultant memory state by consideration of the tripping event(s) of the sense circuit and the information about the applied control gate voltage from the state machine. It then computes a binary encoding for the memory state and stores the resultant data bits into data latches 340.

During program or verify operations for memory cells, the data to be programmed (write data) is stored in the set of data latches 340 from the data bus 334 by way of XDL latches 348. The program operation, under the control of the state machine 262, applies a series of programming voltage pulses to the control gates of the addressed memory cells. Each voltage pulse may be stepped up in magnitude from a previous program pulse by a step size in a process referred to as incremental step pulse programming. In one embodiment, each program voltage is followed by a verify operation to determine if the memory cells have been programmed to the desired memory state. In some cases, managing circuit 330 monitors the read back memory state relative to the desired memory state. When the two agree, managing circuit 330 sets the bit line in a program inhibit mode such as by updating its latches. This inhibits the memory cell coupled to the bit line from further programming even if additional program pulses are applied to its control gate.

FIG. 4 is a perspective view of a portion of one example embodiment of a monolithic three dimensional memory array/structure that can comprise memory structure 202, which includes a plurality non-volatile memory cells arranged as vertical NAND strings. For example, FIG. 4 shows a portion 400 of one block of memory. The structure depicted includes a set of bit lines BL positioned above a stack 401 of alternating dielectric layers and conductive layers. For example purposes, one of the dielectric layers is marked as D. The conductive layers are labeled as one of: SGD, WL, or SGS. An SGD conductive layer serves as drain side select lines. A WL conductive layer serves as a word line. An SGS conductive layer serves as a source side select line. The numbers of each of these conductive layers is limited for ease of illustration. The number of alternating dielectric layers and conductive layers can vary based on specific implementation requirements. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

In one embodiment the block is operated as a number of “sub-blocks.” Each of these “sub-blocks” has many NAND strings. In an embodiment, an isolation region (IR) divides the SGD layers into multiple SGD select lines, each of which is used to select a sub-block (e.g., set of NAND strings). FIG. 4 depicts an example having one IR region and thereby two sub-blocks. However, there may be more than one IR region and thereby more than two sub-blocks. Optionally, the IR region can extend downward through all of the alternating dielectric layers and conductive layers.

FIG. 4A is a block diagram explaining one example organization of memory structure 202, which is divided into two planes 403-A and 403-B. Each plane 403 is then divided into M physical blocks. In one example, each plane has about 2000 physical blocks (or more briefly “blocks”). However, different numbers of blocks and planes can also be used. In one “full-block” embodiment, a block of memory cells is a unit of erase. That is, all memory cells of a block are erased together. In a “sub-block mode” embodiment, blocks are divided into sub-blocks and the sub-blocks are the unit of erase. In an embodiment, a block contains a number of word lines with each sub-block containing a unique set of the data word lines. In an embodiment, each plane 403-A, 403-B has a set of bit lines that extend across all of the blocks in that plane. In an embodiment, one block per plane is selected at a time. Memory cells can also be grouped into blocks for other reasons, such as to organize the memory structure to enable the signaling and selection circuits. In some embodiments, a block represents a groups of connected memory cells as the memory cells of a block share a common set of word lines. For example, the word lines for a block are all connected to all of the vertical NAND strings for that block. Although FIG. 4A shows two planes 403-A, 403-B more or fewer than two planes can be implemented. In some embodiments, memory structure 202 includes four planes. In some embodiments, memory structure 202 includes eight planes. In some embodiments, programming can be performed in parallel in a first selected block in plane 403-A and a second selected block in plane 403-B.

FIGS. 4B-4E depict an example three dimensional (“3D”) NAND structure that corresponds to the structure of FIG. 4 and can be used to implement memory structure 202 of FIGS. 2A and 2B. FIG. 4B is a diagram depicting a top view of a portion 407 of Block 2. As can be seen from FIG. 4B, the physical block depicted in FIG. 4B extends in the direction of arrow 433. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442, and 452. Vertical column 422 implements NAND string 482. Vertical column 432 implements NAND string 484. Vertical column 442 implements NAND string 486. Vertical column 452 implements NAND string 488. More details of the vertical columns are provided below. Since the physical block depicted in FIG. 4B extends in the direction of arrow 433, the physical block includes more vertical columns than depicted in FIG. 4B.

FIG. 4B also depicts a set of bit lines 415, including bit lines 411, 412, 413, 414, . . . 419. FIG. 4B shows twenty-four bit lines because only a portion of the physical block is depicted. It is contemplated that more than twenty-four bit lines connected to vertical columns of the physical block. Each of the circles representing vertical columns has an “x” to indicate its connection to one bit line. For example, bit line 414 is connected to vertical columns 422, 432, 442 and 452.

The physical block depicted in FIG. 4B includes a set of isolation regions 402, 404, 406, 408, and 410, which are formed of SiO₂; however, other dielectric materials can also be used. Isolation regions 402, 404, 406, 408, and 410 serve to divide the top layers of the physical block into four regions; for example, the top layer depicted in FIG. 4B is divided into regions 420, 430, 440, and 450, which are referred to herein as “sub-blocks.” Each sub-block contains a large number of NAND strings. In one embodiment, isolation regions 402 and 410 separate the physical block 407 from adjacent physical blocks. Thus, isolation regions 402 and 410 may extend down to the substrate. In one embodiment, the isolation regions 404, 406, and 408 only divide the layers used to implement select gates so that NAND strings in different sub-blocks can be independently selected. Referring back to FIG. 4, the IR region may correspond to any of isolation regions 404, 406, or 408. In one example implementation, a bit line only connects to one vertical column/NAND string in each of regions (sub-blocks) 420, 430, 440, and 450. In that implementation, each physical block has sixteen rows of active columns and each bit line connects to four NAND strings in each block. In one embodiment, all of the four vertical columns/NAND strings connected to a common bit line are connected to the same word line (or set of word lines); therefore, the system uses the drain side selection lines to choose one (or another subset) of the four to be subjected to a memory operation (program, verify, read, and/or erase).

Although FIG. 4B shows each region (420, 430, 440, 450) having four rows of vertical columns, four regions (420, 430, 440, 450) and sixteen rows of vertical columns in a block, those exact numbers are an example implementation. Other embodiments may include more or fewer regions (420, 430, 440, 450) per block, more or fewer rows of vertical columns per region and more or fewer rows of vertical columns per block. FIG. 4B also shows the vertical columns being staggered. In other embodiments, different patterns of staggering can be used. In some embodiments, the vertical columns are not staggered.

FIG. 4C depicts an example of a stack 435 showing a cross-sectional view along line AA of FIG. 4B. The SGD layers include SGDT0, SGDT1, SGD0, and SGD1. The SGD layers may have more or fewer than four layers. The SGS layers includes SGSB0, SGSB1, SGS0, and SGS1. The SGS layers may have more or fewer than four layers. Six dummy word line layers DD0, DD1, WLIFDU, WLIDDL, DS1, and DS0 are provided, in addition to the data word line layers WL0-WL111. There may be more or fewer than 112 data word line layers and more or fewer than six dummy word line layers. Each NAND string has a drain side select gate at the SGD layers. Each NAND string has a source side select gate at the SGS layers. Also depicted are dielectric layers DL0-DL124.

Columns 432, 434 of memory cells are depicted in the multi-layer stack. The stack includes a substrate 457, an insulating film 454 on the substrate, and a portion of a source line SL. A portion of the bit line 414 is also depicted. Note that NAND string 484 is connected to the bit line 414. NAND string 484 has a source-end at a bottom of the stack and a drain-end at a top of the stack. The source-end is connected to the source line SL. A conductive via 429 connects the drain-end of NAND string 484 to the bit line 414.

In one embodiment, the memory cells are arranged in NAND strings. The word line layers WL0-WL111 connect to memory cells (also called data memory cells). Dummy word line layers DD0, DD1, DS0 and DS1 connect to dummy memory cells. A dummy memory cell does not store and is not eligible to store host data (data provided from the host, such as data from a user of the host), while a data memory cell is eligible to store host data. In some embodiments, data memory cells and dummy memory cells may have the same structure. Drain side select layers SGD are used to electrically connect and disconnect (or cut off) the channels of respective NAND strings from bit lines. Source side select layers SGS are used to electrically connect and disconnect (or cut off) the channels of respective NAND strings from the source line SL.

FIG. 4C depicts an example of a stack 435 having two tiers (lower tier 423, upper tier 421). A two tier or other multi-tier stack can be used to form a relatively tall stack while maintaining a relatively narrow memory hole width (or diameter). After the layers of the lower tier are formed, memory hole portions are formed in the lower tier. Subsequently, after the layers of the upper tier are formed, memory hole portions are formed in the upper tier, aligned with the memory hole portions in the lower tier to form continuous memory holes from the bottom to the top of the stack. The resulting memory hole is narrower than would be the case if the hole were etched from the top to the bottom of the stack rather than in each tier individually. An interface (IF) region is created where the two tiers are connected. The IF region is typically thicker than the other dielectric layers. Due to the presence of the IF region, the adjacent word line layers suffer from edge effects such as difficulty in programming or erasing. These adjacent word line layers can therefore be set as dummy word lines (WLIFDL, WLIFDU). In some embodiments, the tiers are erased independent of one another. Hence, data may be maintained in the upper tier 421 after the lower tier 423 is erased. Likewise, data may be maintained in the lower tier 423 after upper tier 421 is erased.

FIG. 4D depicts a view of the region 445 of FIG. 4C. Data memory cell transistors 520, 521, 522, 523, and 524 are indicated by the dashed lines. A number of layers can be deposited along the sidewall (SW) of the memory hole 432 and/or within each word line layer, e.g., using atomic layer deposition. For example, each column (e.g., the pillar which is formed by the materials within a memory hole) can include a blocking oxide/block high-k material 470, charge-trapping layer or film 463 such as SiN or other nitride, a tunneling layer 464, a polysilicon body or channel 465, and a dielectric core 466. A word line layer can include a conductive metal 462 such as Tungsten as a control gate. For example, control gates 490, 491, 492, 493 and 494 are provided. In this example, all of the layers except the metal are provided in the memory hole. In other approaches, some of the layers can be in the control gate layer. Additional pillars are similarly formed in the different memory holes. A pillar can form a columnar active area (AA) of a NAND string.

When a data memory cell transistor is programmed, electrons are stored in a portion of the charge-trapping layer which is associated with the data memory cell transistor. These electrons are drawn into the charge-trapping layer from the channel, and through the tunneling layer. The Vt of a data memory cell transistor is increased in proportion to the amount of stored charge. During an erase operation, the electrons return to the channel.

Each of the memory holes can be filled with a plurality of annular layers (also referred to as memory film layers) comprising a blocking oxide layer, a charge trapping layer, a tunneling layer and a channel layer. A core region of each of the memory holes is filled with a body material, and the plurality of annular layers are between the core region and the WLLs in each of the memory holes. In some cases, the tunneling layer 464 can comprise multiple layers such as in an oxide-nitride-oxide configuration.

FIG. 4E is a schematic diagram of a portion of the memory array 202. FIG. 4E shows physical data word lines WL0-WL111 running across the entire block. The structure of FIG. 4E corresponds to a portion 407 in Block 2 of FIG. 4A, including bit line 411. Within the physical block, in one embodiment, each bit line is connected to four NAND strings. Thus, FIG. 4E shows bit line 411 connected to NAND string NS0, NAND string NS1, NAND string NS2, and NAND string NS3.

In one embodiment, there are four sets of drain side select lines in the physical block. For example, the set of drain side select lines connected to NS0 include SGDT0-s0, SGDT1-s0, SGD0-s0, and SGD1-s0. The set of drain side select lines connected to NS1 include SGDT0-s1, SGDT1-s1, SGD0-s1, and SGD1-s1. The set of drain side select lines connected to NS2 include SGDT0-s2, SGDT1-s2, SGD0-s2, and SGD1-s2. The set of drain side select lines connected to NS3 include SGDT0-s3, SGDT1-s3, SGD0-s3, and SGD1-s3. Herein the term “SGD” may be used as a general term to refer to any one or more of the lines in a set of drain side select lines. In some embodiments, the same operating voltage is applied to SGDT0 and SGDT1. In some embodiments, the same operating voltage is applied to SGD0 and SGD1. In some erase embodiments, different operating voltage are applied to SGDT0/SGDT1 than to SGD0/SGD1. Note that SGDT0/SGDT1 are adjacent to the bit line. In some erase embodiments, a voltage applied to SGDT0/SGDT1 in combination with a bit line voltage may be used to generate a gate induced gate leakage (GIDL) current. Such a voltage applied to SGDT0/SGDT1 may be referred to herein as a GIDL voltage.

In an embodiment, each line in a given set may be operated independent from the other lines in that set to allow for different voltages to the gates of the four drain side select transistors on the NAND string. Moreover, each set of drain side select lines can be selected independent of the other sets. Each set drain side select lines connects to a group of NAND strings in the block. Only one NAND string of each group is depicted in FIG. 4E. These four sets of drain side select lines correspond to four “sub-blocks.” A first sub-block corresponds to those vertical NAND strings controlled by SGDT0-s0, SGDT1-s0, SGD0-s0, and SGD1-s0. A second sub-block corresponds to those vertical NAND strings controlled by SGDT0-s1, SGDT1-s1, SGD0-s1, and SGD1-s1. A third sub-block corresponds to those vertical NAND strings controlled by SGDT0-s2, SGDT1-s2, SGD0-s2, and SGD1-s2. A fourth sub-block corresponds to those vertical NAND strings controlled by SGDT0-s3, SGDT1-s3, SGD0-s3, and SGD1-s3. As noted, FIG. 4E only shows the NAND strings connected to bit line 411. However, a full schematic of the block would show every bit line and four vertical NAND strings connected to each bit line.

Although the example memories of FIGS. 4-4E are three dimensional memory structure that includes vertical NAND strings with charge-trapping material, other 3D memory structures can also be used with the technology described herein.

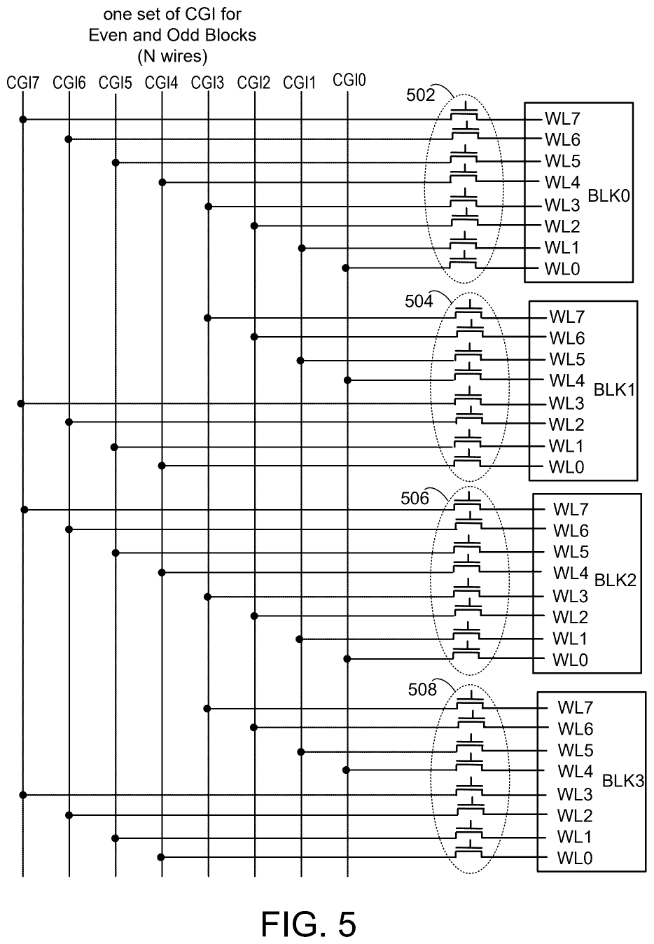

FIG. 5 depicts an embodiment of circuitry for providing voltages to blocks of memory cells. The circuitry is able to test multiple blocks of memory cells with a single set of CGI lines. The single set of CGI lines may also be used for normal memory operations such as read, write, and erase. This example has eight CGI lines: CGI0, CGI1, CGI2, CGI3, CGI4 CGI5, CGI6, and CGI7. The number of CGI lines will depend on the number of word lines per block. In this example, only eight word lines (WL0-WL7) are depicted per block; however, there may be hundreds of word lines per block. Each block will also have other control lines such as select lines (e.g., SGD, SGS) and dummy word lines (see, for example, FIG. 4C); however, those other control lines are not depicted in FIG. 5. Other CGI lines may be added to provide voltages for those other control lines. Thus, typically there will be many more than eight CGI lines.

Each block (BLK0, BLK1, BLK2, BLK3) of memory cells is associated with a set of word line switches (also referred to as transfer transistors). Only four blocks are depicted, but typically there will be many more blocks on a memory die. Word line switch transistors (also referred to as WLSW transistors) 502 are associated with BLK0, word line switch transistors 504 are associated with BLK1, word line switch transistors 506 are associated with BLK2, and word line switch transistors 508 are associated with BLK3. Each word line switch transistor is connected to one of the CGI lines such that the CGI line may provide a voltage to a terminal (e.g., drain) of the word line switch transistor. Word line drivers may provide the voltages to the CGI lines; however, the word line drivers are not depicted in FIG. 5. Each word line switch transistor may be an nMOSFET, for example, which has a drain node on the left hand side and a source node on the right hand side (connected to the associated word line in the block). Each voltage driver may include an on-chip charge pump. Each voltage driver can be independently controlled to provide a desired output voltage to a CGI line. A decoder circuit (not depicted in FIG. 5) may provide decoder signals to the control gates of the word line switch transistors to selectively pass the voltages on the CGI lines to the word lines in selected blocks. In an embodiment, the memory system will select two adjacent blocks at a time for a test. These tests could include leakage current tests and/or stress tests. The circuitry may be used to apply a different voltage to word lines that neighbor each other in the two adjacent blocks. For example, a high voltage could be applied to WL0 in BLK0 by providing a high voltage on CGI0 while applying a low voltage to WL0 in BLK1 by providing a low voltage on CGI4. In this example, the word lines are numbered according to their physical position in the block. In some embodiments the word lines have addresses that correspond to these physical positions within the block. In the example in FIG. 5 the word lines are numbered low to high from bottom to top, but the ordering could be reversed. Note that the word lines in FIG. 5 may be connected to NAND strings, as in the example in FIG. 4E. Table I summarizes an example mapping between the CGI lines and the word lines in the even and odd blocks. Note that the mapping to word lines may also be viewed as a mapping to the corresponding WLSW transistors.

TABLE I

| | Even Blocks | Odd Blocks |
|---|---|---|
| CGI0 | WL0 | WL4 |
| CGI1 | WL1 | WL5 |
| CGI2 | WL2 | WL6 |
| CGI3 | WL3 | WL7 |
| CGI4 | WL4 | WL0 |
| CGI5 | WL5 | WL1 |
| CGI6 | WL6 | WL2 |
| CGI7 | WL7 | WL3 |

In the example in Table I, the mapping from the CGI lines to the word lines in the even blocks follows the numbering of the CGI lines. However, the mapping from the CGI lines to the word lines in the odd blocks has a “swapping of word lines.” In particular, WL0-WL3 are swapped with WL4-WL7 in the odd blocks (relative to the even blocks). In this example, this swapping involves groups of four word lines, but the swapping can involve groups having more or fewer than four word lines. Also, only two WL groups are depicted in Table I; however, there may be more than two WL groups. Note that in Table I each CGI line is mapped to a different numbered word line in the even block than the odd block. Note also that in in Table I each numbered word line in an odd block is mapped to a different CGI than the same numbered word line in an even block. For example, WL3 in the odd block is mapped to CGI7, but WL3 in the even block is mapped to CGI3, which allows different voltages to be provided to WL3 in the odd and even block. Providing different voltages to the same numbered word line in two adjacent blocks is very useful for tests including, but not limited to, current leakage between word lines in adjacent blocks and stress tests involving adjacent blocks. The foregoing discussion of the mapping between the CGI lines to word lines (based on WL numbers) also applies to mapping between the CGI lines to WLSW transistors.

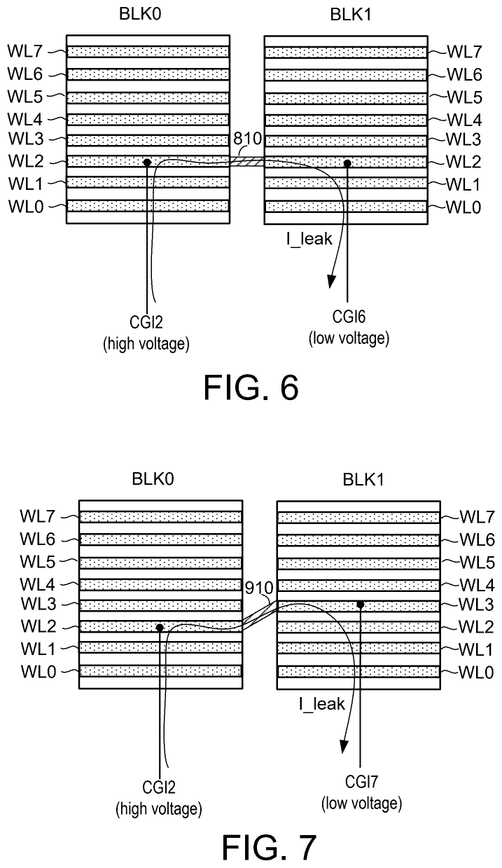

FIG. 6 depicts an example of how an embodiment of the circuitry in FIG. 5 may be used to perform a current leakage test to determine whether there may be a short circuit between word lines in two adjacent blocks. In particular, FIG. 6 depicts an example of test for a leakage current between WL2 in BLK0 and WL2 in BLK1. Such a leakage current may result if there is a short circuit defect 810 between WL2 in BLK0 and WL2 in BLK1. FIG. 6 shows the CGI lines involved in the leakage tests, but for simplicity does not show the word line switches. A driver (not shown in FIG. 6) may provide a high voltage to CGI2. This high voltage is passed to WL2 in BLK0 by a word line switch (not depicted in FIG. 6. A driver (not shown in FIG. 6) may provide a low voltage to CGI6. This low voltage is passed to WL2 in BLK1 by a word line switch (not depicted in FIG. 6. Due to the short circuit defect 810 between WL2 in BLK0 and WL2 in BLK1 a leakage current (I_leak) may flow. The memory system is able to test for this leakage current to detect the presence of the short circuit defect 810 between WL2 in BLK0 and WL2 in BLK1. Significantly, a single set of CGI lines (having the same number of lines as there are word lines in a block) may be used to apply the two different voltages to the adjacent word lines in the adjacent even/odd blocks.

An embodiment of the circuitry of FIG. 5 may test for a short circuit defect between a word line in an odd block at a different level than a word line in an adjacent even block. FIG. 7 depicts an example of how an embodiment of the circuitry in FIG. 5 may be used to perform such a current leakage test. In particular, FIG. 7 depicts an example of test for a leakage current between WL2 in BLK0 and WL3 in BLK1. Such a leakage current may result if there is a short circuit defect 910 between WL2 in BLK0 and WL3 in BLK1. FIG. 7 shows the CGI lines involved in the leakage test, but for simplicity does not show the word line switches. A driver (not shown in FIG. 6) may provide a high voltage to CGI2. This high voltage is passed to WL2 in BLK0 by a word line switch (not depicted in FIG. 6). A driver (not shown in FIG. 6) may provide a low voltage to CGI7. This low voltage is passed to WL3 in BLK1 by a word line switch (not depicted in FIG. 6). Due to the short circuit defect 910 between WL2 in BLK0 and WL3 in BLK1 a leakage current (I_leak) may flow. The memory system is able to test for this leakage current to detect the presence of the short circuit defect 910 between WL2 in BLK0 and WL3 in BLK1. Significantly, a single set of CGI lines (having the same number of lines as there are word lines in a block) may be used to apply the two different voltages to these two word lines in the adjacent even/odd blocks. This ability to test for short circuit defects may be applied to other word lines such as, for example, between WL2 in BLK0 and WL1 in BLK1, WL2 in BLK0 and WL0 in BLK1, WL0 in BLK0 and WL3 in BLK1, etc. This ability in general applies to any two word lines in the same word line group. For example, in Table I there are four word line in each of two word line groups. One group has WL0-WL3, the other group has WL4-WL7. Thus, the testing may be between any two word lines in a group.

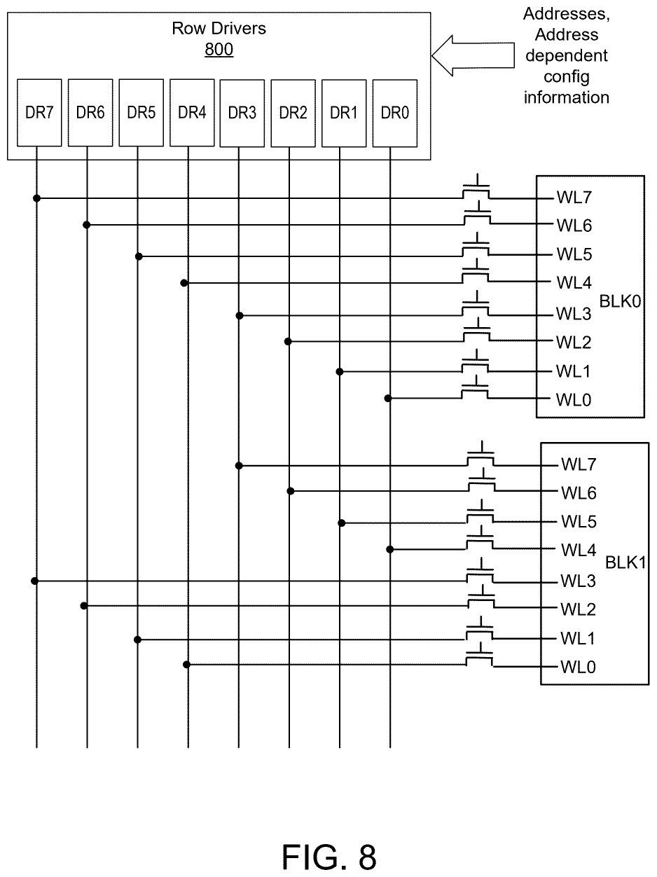

The circuitry depicted in FIG. 5 may also be used for normal memory operations such as read, write, and erase. For such normal memory operations typically only one block is selected at a time. FIG. 8 shows further details of an embodiment of circuitry for providing voltages to word lines. The circuitry may be used for normal memory operations such as read, write, and erase, as well as for testing a pair of adjacent blocks. An example even block (BLK0) and an example odd block (BLK1) is depicted. Consistent with the example in FIG. 5, there are eight word lines per block and eight CGI lines. FIG. 8 shows row drivers 800, which include eight drivers DR0-DR7. Each driver is connected to one CGI line. The eight drivers DR0-DR7 thus provide voltage to CGI0-CGI7, respectively. Each row driver (also referred to as word line drivers) will apply a voltage to its CGI depending on the block address. Each row driver will apply a voltage to its CGI depending on whether the block address is even of odd. As a specific example when reading WL2 in an even block, a read reference voltage is applied by DR2 to CGI2. However, when reading WL2 in an odd block, the read reference voltage is applied by DR6 to CGI6. The row drivers 800 receive addresses and address dependent configuration information in order to provide the proper voltages to the proper CGI lines.

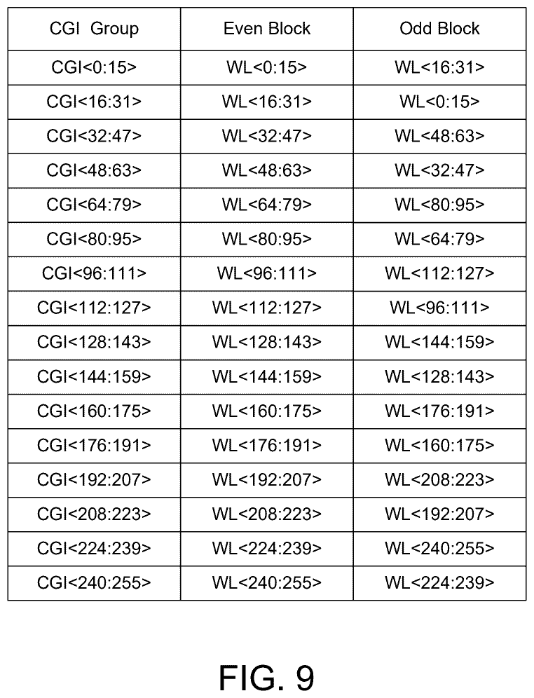

As noted herein, there may be a swapping of word line groups such that a group of CGI lines will be used to provide voltages for a first range of word line numbers in even blocks and a second range of word line number in odd blocks. The groups may be of any size. FIG. 9 shows a table of an example mapping of CGI lines to word lines in even and odd blocks. The CGI lines are divided into 16 different groups with 16 CGI lines in each group. Similarly, the word line are divided into 16 different groups with 16 word lines in each group. Each row of the table shows the mapping for one group of CGI lines to even and odd blocks. Note that for each group of word lines the range of word line numbers in the even block is different than the range of word line numbers for the odd block. Note that a short may be detected between any word line pair WL<j>, WL<i> of adjacent blocks as long as |i−j|<16. In this example, the numbering for the word lines in the even blocks is the same as the numbering of the CGI lines (e.g., CGI0 to WL0, CGI1 to WL1, etc.). However, there is a swapping of word line groups for the odd blocks relative to the even blocks. For example, WL0-WL15 are swapped with WL16-31 for odd blocks relative to the even blocks. This word line swapping concept is also depicted in FIGS. 5 and 8 (as well as Table I), but for different group sizes. Therefore, the embodiments in FIGS. 5 and 8 may be modified to accommodate the Table in FIG. 9.

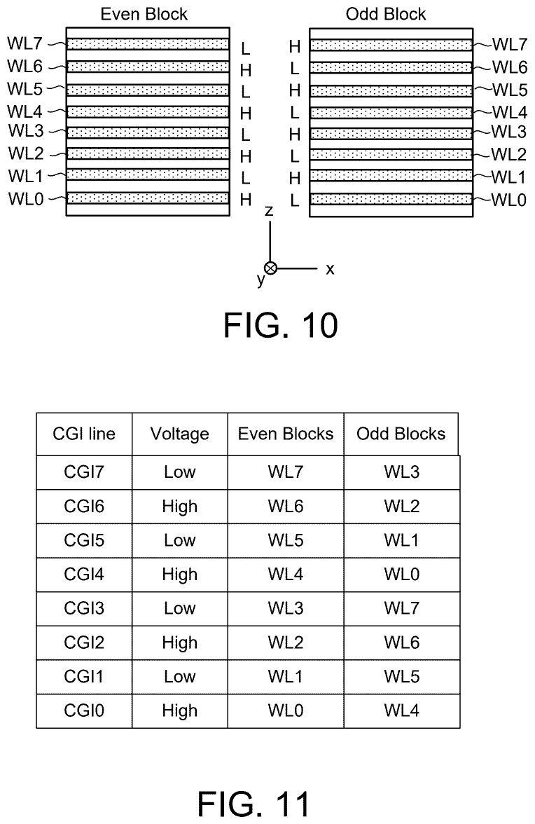

In some embodiments, the memory system performs a stress test in which a high voltage is applied to a word line in one block and a low voltage is applied to the neighboring word line in an adjacent block. Here, the neighboring word line refers to a word line at the same level of the memory stack (e.g., the same word line number). FIG. 10 shows an example of voltages that may be applied to an even block and an odd block during a stress test. This simple example has eight word lines per block, but typically there will be more than eight word lines. In this example, the voltages within an even block alternate between high (H) and low (L) from lowest number word line (WL0) to highest numbered word line (WL7). However, the voltages within an odd block alternate between low (L) and high (H) from lowest number word line (WL0) to highest numbered word line (WL7). Therefore, for each pair of word lines having the same word line number (but it different blocks) one word line has a high voltage and the other has a low voltage. Note that word line addresses may be assigned based on physical location within a block in which case it may be stated that for each pair of word lines having the same address within a block (but in different blocks) one word line has a high voltage and the other has a low voltage. The difference in magnitude between the high and low voltages is sufficient to create stress. Such as stress test could potentially bring out a short circuit, which may be detected in a current leakage test. The stress test may be performed at any time, but is sometime performed at the factory prior to shipping the memory system to a customer. In some embodiment, the memory system will retire adjacent blocks if a short circuit is detected between the adjacent blocks.

FIG. 11 is a table depicting an example of mapping a set of CGI lines to word lines in even and odd blocks for a stress test. Example voltages provided by each CGI line are also depicted. The example values in the table in FIG. 11 are consistent with the stress test example in FIG. 10. In the example in FIG. 11, the mapping from the CGI lines to the word lines in the even blocks follows the numbering of the CGI lines. However, the mapping from the CGI lines to the word lines in the odd blocks has a “swapping of word lines.” In particular, WL0-WL3 are swapped with WL4-WL7 in the odd blocks (relative to the even blocks). In this example, this swapping involves groups of four word lines, but the swapping can involve groups having more or fewer than four word lines. Also, only two WL groups are depicted in the table; however, there may be more than two WL groups.

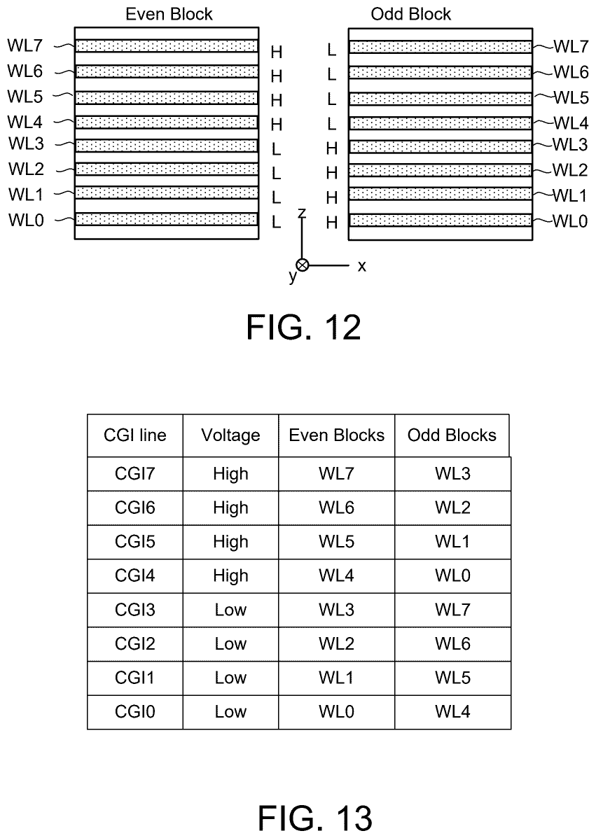

FIG. 12 shows another example of voltages that may be applied to an even block and an odd block during a stress test. This simple example has eight word lines per block, but typically there will be more than eight word lines. In this example, the voltages within an even block have a first group of contiguous word lines with a high voltage (H) and a second group of contiguous word lines with a low voltage (L). The voltages within an odd block have a first group of contiguous word lines with a low voltage (L) and a second group of contiguous word lines with a high voltage (H). Note that for each pair of word lines having the same word line number (but in different blocks) one word line has a high voltage and the other has a low voltage. The difference in magnitude between the high and low voltages is sufficient to create stress. Such as stress test could potentially bring out a short circuit, which may be detected in a current leakage test. The stress test may be performed at any time, but is sometime performed at the factory prior to shipping the memory system to a customer.

FIG. 13 is a table depicting an example of mapping a set of CGI lines to word lines in even and odd blocks for a stress test. Example voltages provided by each CGI line are also depicted. The example values in the table in FIG. 13 are consistent with the stress test example in FIG. 12. In the example in FIG. 13, the mapping from the CGI lines to the word lines in the even blocks follows the numbering of the CGI lines. However, the mapping from the CGI lines to the word lines in the odd blocks has a “swapping of word lines.” In particular, WL0-WL3 are swapped with WL4-WL7 in the odd blocks relative to the even blocks. In this example, this swapping involves groups of four word lines, but the swapping can involve groups having more or fewer than four word lines. Also, only two WL groups are depicted in the table; however, there may be more than two WL groups.

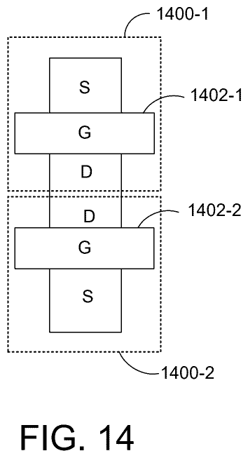

FIG. 14 shows details two example WLSW transistors. In an embodiment, the WLSW transistors reside on the memory die 200. In an embodiment, the WLSW transistors reside on the control die 211. One WLSW transistor 1400-1 may be used to provide a voltage to a word line in an even block and the other WLSW transistor 1400-2 may be used to provide a voltage to a word line in an odd block. The WLSW transistors share an active area (AA) that may be doped to formed source regions(S) and drain regions (D). The source(S) regions are connected to the respective word lines. For example, source(S) of WLSW transistor 1400-1 may be connected to a word line in an even block and source(S) of WLSW transistor 1400-2 may be connected to a word line in an odd block. Gate 1402-1 is to control WLSW transistor 1400-1 and gate 1402-2 is to control WLSW transistor 1400-2. For example, decode signals (e.g., block select) may be provided to the gates to select either or both WLSW transistors to pass the voltages at the drain(s) to the word lines in the respective blocks. In an embodiment, the drain region (D) is shared by the two WLSW transistors 1400-1, 1400-2. However, each WLSW transistor could have its own separate drain region. The drain is connected to a CGI line. Thus, in the example in FIG. 14, both WLSW transistors 1400-1, 1400-2 are connected to the same CGI line. However, it is not a requirement that each WLSW transistor 1400-1, 1400-2 be connected to the same CGI line.

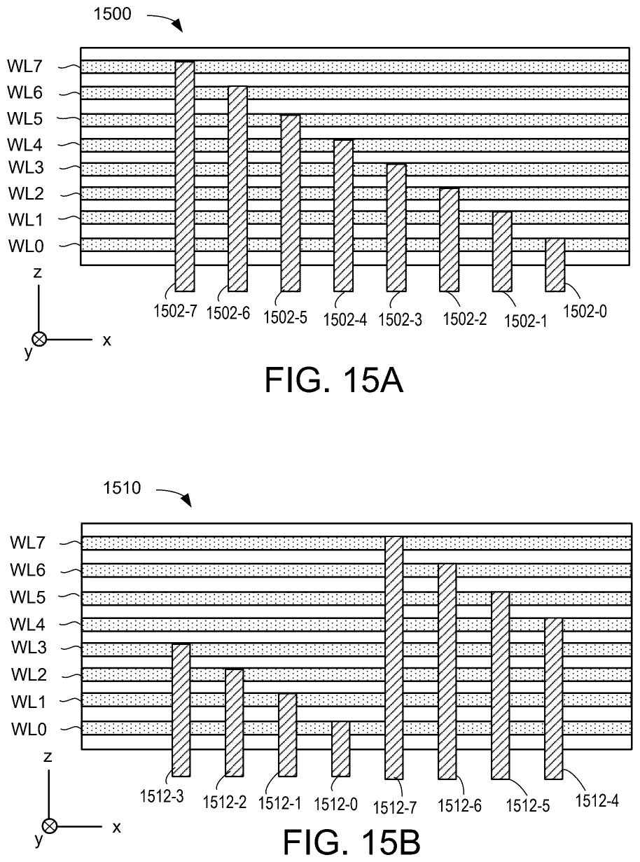

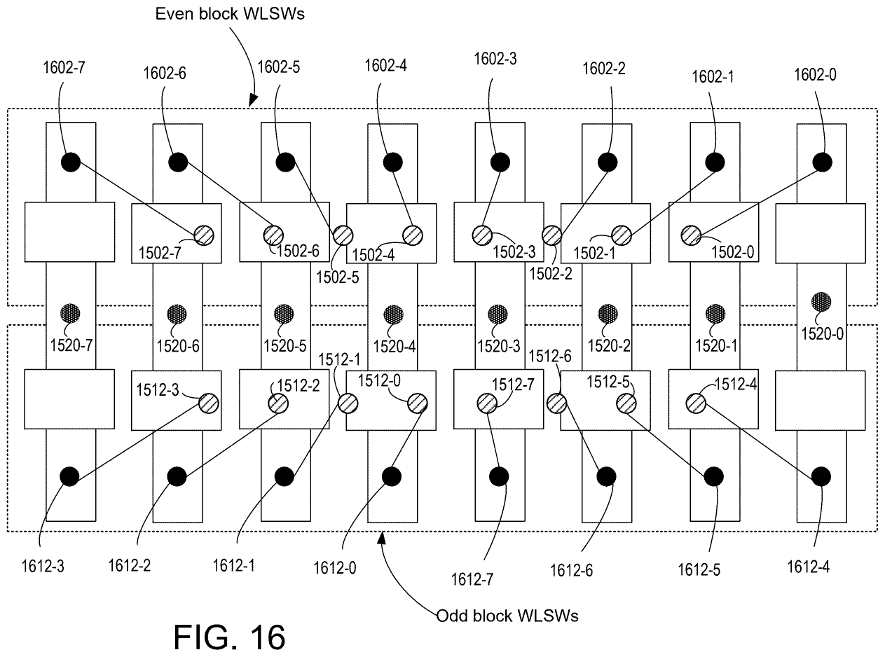

FIGS. 15A, 15B, and 16 will now be discussed as an embodiment for routing between WLSW transistors and word lines. FIG. 15A shows a cross sectional view of an even block 1500. FIG. 15B shows a cross sectional view of an odd block 1510. Consistent with other examples only eight word line are depicted, but there will typically be hundreds of word lines as well as other control lines (e.g., select lines) in each block. In FIG. 15A, one end of each word line contact 1502-0, 1502-1, 1502-2, 1502-3, 1502-4, 1502-5, 1502-6, 1502-7 connects to and provides a voltage to WL0-WL7, respectively, in the even block 1500. In FIG. 15B, one end of each word line contact 1512-0, 1512-1, 1512-2, 151-3, 1512-4, 1512-5, 1512-6, 1512-7 connects to and provides a voltage to WL0-WL7, respectively, in the odd block 1510. Note that the stagger pattern of the word line contacts 1512 in the odd block 1510 is different than the stagger pattern for the word line contacts 1502 in the even block 1500.

FIG. 16 shows a WLSW transistors for an even block and for an odd block. The WLSW transistors have the configuration depicted in FIG. 14 in which two WLSW transistors share a common drain. Thus, FIG. 16 depicts two rows of WLSW transistors with eight WLSW transistors in each row. The top row of WLSW transistors are for an even block and the bottom row of WLSW transistors are for an odd block. The top row of WLSW transistors have source contacts 1602-0, 1602-1, 1602-2, 1602-3, 1602-4, 1602-5, 1602-6, and 1602-7, which connect to the source regions of those WLSW transistors. These source contacts 1602 are connected to word line contacts 1502-0, 1502-1, 1502-2, 1502-3, 1502-4, 1502-5, 1502-6, 1502-7, respectively. Therefore, the transistors having source contacts 1602-0, 1602-1, 1602-2, 1602-3, 1602-4, 1602-5, 1602-6, and 1602-7 are connected to and provide voltages to WL0, WL1, WL2, WL3, WL4, WL5, WL6, and WL7, respectively, in the even block. The bottom row of WLSW transistors have source contacts 1612-4, 1612-5, 1612-6, 1612-7, 1612-0, 1612-1, 1612-2, and 1612-3. These source contacts are connected to word line contacts 1512-4, 1512-5, 1512-6, 1512-7, 1512-0, 1512-1, 1512-2, and 1512-3, respectively. Therefore, the transistors having source contacts 1612-4, 1612-5, 1612-6, 1612-7, 1612-0, 1612-1, 1612-2, and 1612-3 are connected to and provide voltages to WLA, WL5, WL6, WL7, WL0, WL1, WL2, and WL3, respectively, in the odd block.

The configuration depicted in FIG. 16 is one embodiment of routing to achieve the mapping between CGI lines and word lines discussed with respect to Table I above, as well as the table in FIG. 13. Therefore, the CGI lines may be connected to the drain contacts 1520 in FIG. 15 as follows. Drain region contact 1520-7 connects to CGI7, drain region contact 1520-6 connects to CGI6, drain region contact 1520-5 connects to CGI5, drain region contact 1520-4 connects to CGI4, drain region contact 1520-3 connects to CGI3, drain region contact 1520-2 connects to CGI2, drain region contact 1520-1 connects to CGI1, and drain region contact 1520-0 connects to CGI0.

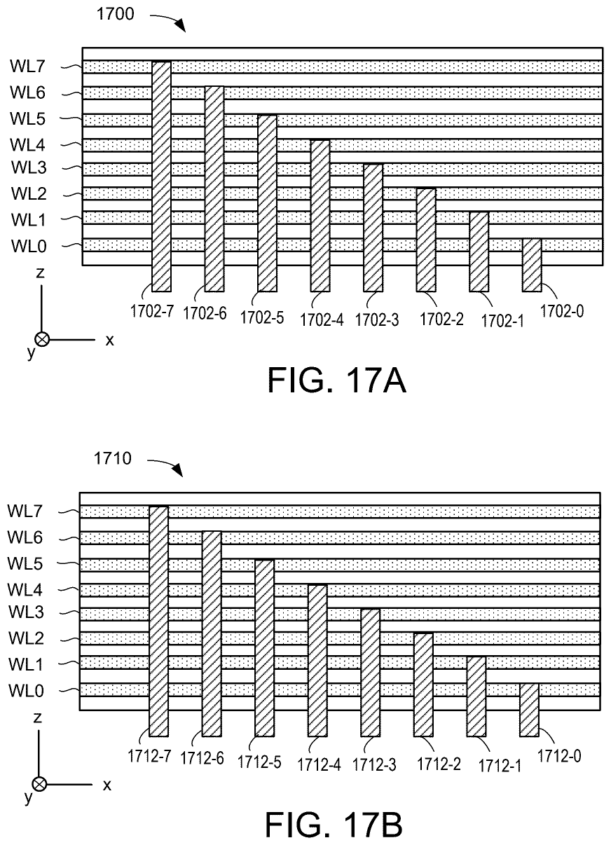

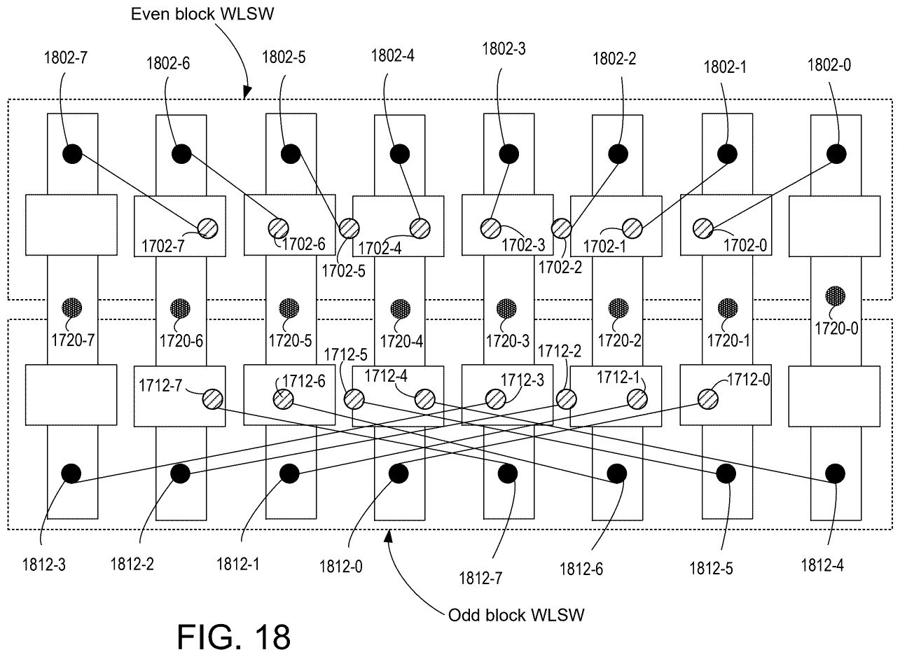

FIGS. 17A, 17B, and 18 will now be discussed as an example embodiment for routing between WLSW transistors and word lines. FIG. 17A shows a cross sectional view of an even block 1700. FIG. 17B shows a cross sectional view of an odd block 1710. Consistent with other examples only eight word line are depicted, but there will typically be hundreds of word lines as well as other control lines (e.g., select lines) in each block. In FIG. 17A, one end of each word line contact 1702-0, 1702-1, 1702-2, 1702-3, 1702-4, 1702-5, 1702-6, 1702-7 connects to and provide a voltage to WL0-WL7, respectively, in the even block 1700. In FIG. 17B, end of each word line contact 1712-0, 1712-1, 1712-2, 171-3, 1712-4, 1712-5, 1712-6, 1712-7 connects to and provide a voltage to WL0-WL7, respectively, in the odd block 1710. Note that the stagger pattern of the word line contacts 1702 in the even block 1700 is the same for the word line contacts 1712 in the odd block 1710.

FIG. 18 shows a WLSW transistors for an even block and for an odd block. The WLSW transistors have the configuration depicted in FIG. 14 in which two WLSW transistors share a common drain. Thus, FIG. 18 depicts two rows of WLSW transistors with eight WLSW transistors in each row. The top row of WLSW transistors are for an even block and the bottom row of WLSW transistors are for an odd block. The top row of WLSW transistors have source contacts 1802-0, 1802-1, 1802-2, 1802-3, 1802-4, 1802-5, 1802-6, and 1802-7, which connect to the source regions of those WLSW transistors. These source contacts 1802 are connected to word line contacts 1702-0, 1702-1, 1702-2, 1702-3, 1702-4, 1702-5, 1702-6, 1702-7, respectively. Therefore, the transistors having source contacts 1802-0, 1802-1, 1802-2, 1802-3, 1802-4, 1802-5, 1802-6, and 1802-7 are connected to and provide voltages to WL0, WL1, WL2, WL3, WL4, WL5, WL6, and WL7, respectively, in the even block 1700. The bottom row of WLSW transistors have source contacts 1812-4, 1812-5, 1812-6, 1812-7, 1812-0, 1812-1, 1812-2, and 1812-3. These source contacts are connected to word line contacts 1712-4, 1712-5, 1712-6, 1712-7, 1712-0, 1712-1, 1712-2, and 1712-3, respectively. Therefore, the transistors having source contacts 1812-4, 1812-5, 1812-6, 1812-7, 1812-0, 1812-1, 1812-2, and 1812-3 are connected to and provide voltages to WL4, WL5, WL6, WL7, WL0, WL1, WL2, and WL3, respectively, in the odd block 1710.

The configuration depicted in FIG. 18 is one embodiment of routing to achieve the mapping between CGI lines and word lines discussed with respect to Table I above, as well as the table in FIG. 13. Therefore, the CGI lines may be connected to the drain contacts 1720 in FIG. 17 as follows. Drain region contact 1720-7 connects to CGI7, drain region contact 1720-6 connects to CGI6, drain region contact 1720-5 connects to CGI5, drain region contact 1720-4 connects to CGI4, drain region contact 1720-3 connects to CGI3, drain region contact 1720-2 connects to CGI2, drain region contact 1720-1 connects to CGI1, and drain region contact 1720-0 connects to CGI0.

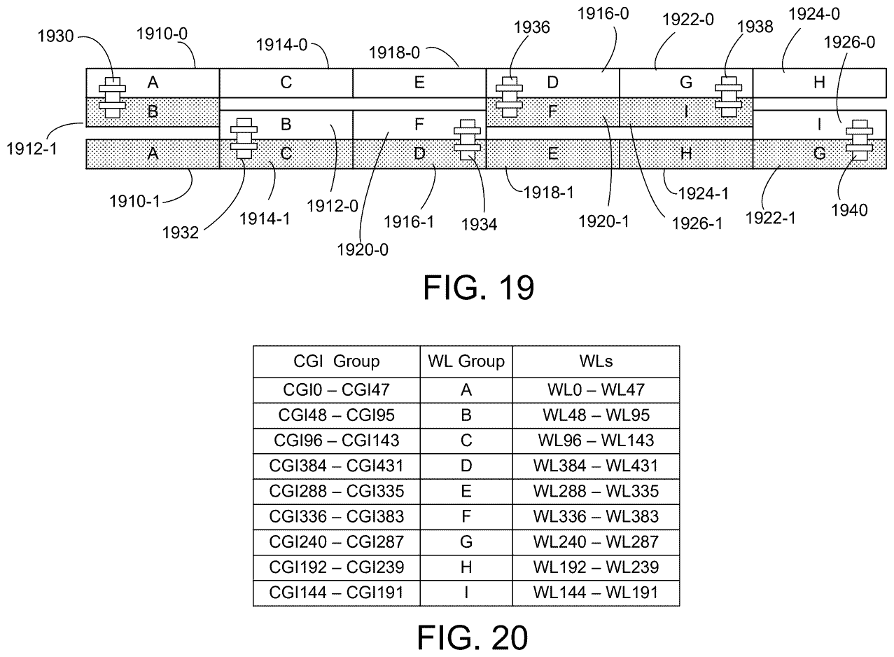

In an embodiment, the WLSW transistors are in a physical layout of three rows of WLSW transistors per two blocks of memory cells. FIG. 19 depicts an embodiment of a physical layout of WLSW transistors. There are three rows of WLSW transistors per two blocks of memory cells. The letters (A-I) refer to a group of word lines. The table in FIG. 20 shows one example of how the word lines may be placed into nine groups (A-I). The table in FIG. 20 also shows have CGI lines groups may be mapped to the word line groups. For example, WL group A has WL0-WL47 with CGI0-CGI47 mapping to WL group A. A detailed list of the CGI lines and WLs is not provided, but the mapping may be as follows: CGI0: WL0, CGI1: WL1, CGI2: WL2, etc. Referring again to FIG. 19, the regions with letters A-I are either shaded white for even blocks or have a dotted shading for odd blocks. For example, region 1910-0 is the area in which the WLSW transistors for WL group A are located for an even block, region 1912-0 is the area in which the WLSW transistors for WL group B are located for the even block, region 1914-0 is the area in which the WLSW transistors for WL group C are located for the even block, etc. Region 1910-1 is the area in which the WLSW transistors for WL group A are located for an odd block, region 1912-1 is the area in which the WLSW transistors for WL group B are located for the odd block, region 1914-1 is the area in which the WLSW transistors for WL group C are located for the odd block, etc. At least some of the regions have WLSW transistors having the configuration depicted in FIG. 14 in which there are two WLSW transistors sharing a drain. An example WLSW transistor 1930 is depicted for region 1910-0 and region 1912-1. WLSW transistor 1930 is one of the many WLSW transistor 1930 in region 1910-0 and region 1912-1. Note that region 1910-0 is for WL group A for an even block, but that region 1912-1 is for WL group B for an odd block, which provides for WL group swapping. The CGI lines that are connected to drains of WLSW transistors 1930 for region 1910-0 and 1912-1 are CGI0-CGI47. Therefore, for the even block CGI0-CGI47 map to WL0-WL47 (WL Group A), respectively. However, for the even block CGI0-CGI47 map to WL48-WL95 (WL Group B), respectively. Similar reasoning applies to WLSW transistor 1932 for even region 1912-0 for WL Group B and odd region 1914-1 for WL Group C; WLSW transistor 1934 for even region 1920-0 for WL Group F and odd region 1916-1 for WL Group D; WLSW transistor 1936 for even region 1916-0 for WL Group D and odd region 1920-1 for WL Group F; WLSW transistor 1938 for even region 1922-0 for WL Group G and odd region 1926-1 for WL Group I; and WLSW transistor 1940 for even region 1926-0 for WL Group I and odd region 1922-1 for WL Group G.

Some of regions in FIG. 19 do not depict WLSW transistors having shared drains (e.g., odd region 1910-1 for WL Group A, even region 1914-0 for WL Group C, even region 1918-0 for WL Group E, odd region 1918-1 for WL Group E, odd region 1924-1 for WL Group H, and even region 1924-0 for WL Group H). Such regions may have the drains of the WLSW transistors connected to the corresponding CGI group listed in FIG. 20.

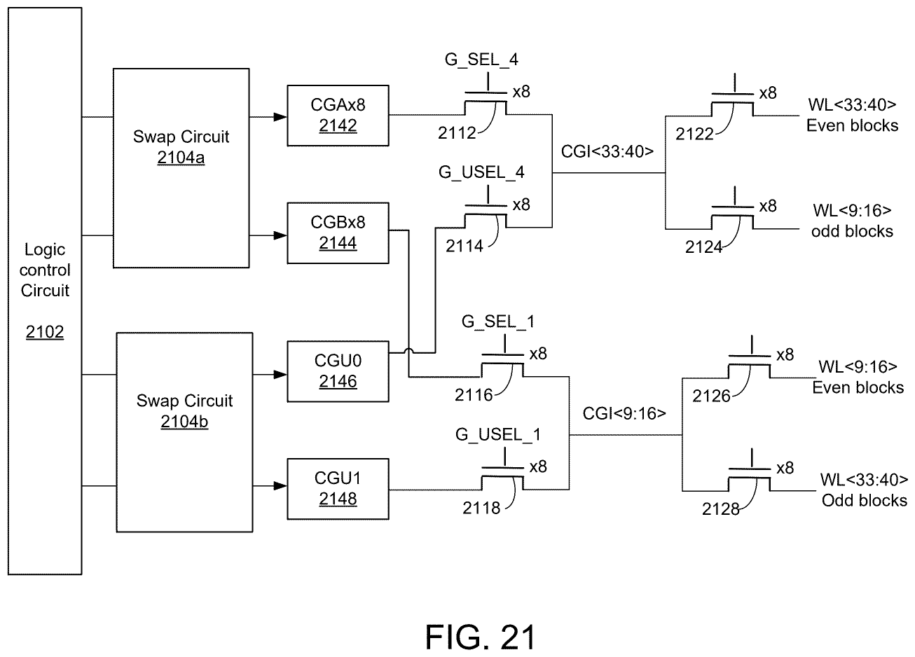

FIG. 21 depicts one embodiment of details of the circuitry for swapping of the word lines groups in connection with the CGI lines. The circuitry contains drivers 2142, 2144, 2146, and 2148. Drivers CGAx8 2142 contain eight drivers for providing voltages to the selected word-line and unselected word-lines close to the selected word-line. Likewise, drivers CGBx8 2144 contain eight drivers for providing voltages to the selected word-line and unselected word-lines close to the selected word-line. Drivers CGU0 2146 and CGU1 2148 are for providing voltages to unselected word-lines farther from the selected lines and thus have simpler voltage requirements. Although all word-lines have corresponding CGA, B, or U drivers, only portion of them involved in the swap operation are shown. Also depicted are high voltage switches (HVSW) 2112, 2114, 2116, 2116 for passing the driver voltage to the CGI lines. HVSW switches 2112 will pass the voltage from drivers CGAx8 2142 to CGI<33:40> if G_SEL_4 is high. HVSW switches 2114 will pass the voltage from drivers CGU0 2146 to CGI<33:40> if G_USEL_4 is high. HVSW switches 2116 will pass the voltage from drivers CGBx8 2144 to CGI<9:16> if G_SEL_1 is high. HVSW switches 2118 will pass the voltage from drivers CGU1 2148 to CGI<9:16> if G_USEL_1 is high. Also depicted are word line switches 2122, 2124, 2126, 2128. The eight word line switches 2122 provide voltages to WL<33:40> in an even block. The eight word line switches 2124 provide voltages to WL<9:16> in an odd block. Note that both word line switches 2122, 2124 are connected to CGI<33:40>, which in turn may be driven by either HVSW 2112 (when block is selected) or HVSW 2114 (when block is not selected).

The swap circuits 2104a, 2104b may be used to control the HVSW switches 2112, 2114, 2116, 2116 to cither swap or not swap. The logic circuit 2102 may send addresses and address configuration information to the circuits 2104a, 2104b. For example, when one of the WL<33:40> in the even block is selected, voltages from drivers CGAx8 2142 are passed by HVSW 2112 to CGI<33:40>. However, when one of the WL<33:40> in the odd block is selected, voltages from drivers CGBx8 2144 are passed by HVSW 2112 to CGI<9:16>, thereby resulting in a swapping. When one of WL<9:16> in the even block is selected, voltages from drivers CGBx8 2144 are passed by HVSW 2116 to CGI<9:16>. However, when one of WL<9:16> in the odd block is selected, voltages from drivers CGAx8 2142 are passed by HVSW 2112 to CGI<33:40>, thereby resulting in a swapping. The foregoing may also swap along a control boundary to avoid additional transistors or analog drivers.

The concepts of mapping the set of CGIs to word lines may also be applied to other control lines such as SGD, SGS and dummy word lines. However, in some cases the drivers for certain control lines such as SGD and/or SGS may have different characteristics (e.g., provide different magnitude voltages) such that swapping between a select line (e.g., SGS, SGD) and a word line is not performed due to the different voltage requirements. In other words, in an embodiment, a CGI line does not connect to an SGD line for even blocks and a word line for odd blocks due to different voltage requirements of SGD compared to word lines. However, a single set of CGI lines could be used for control lines in a similar way that a single set of CGI lines are used for the word lines. In an embodiment, the SGD lines, the SGS lines, and/or dummy word lines have a swapping concept such as in FIG. 18 in which the swapping may be implemented by the different connections between the source contacts and the word line contacts used in even versus odd blocks.

In view of the foregoing, an embodiment includes an apparatus comprising a set of “n” drivers, a plurality of sets of “n” word line switches, and a set of “n” common global interconnect (CGI) lines coupled between the “n” drivers and the plurality of sets of “n” word line switches. Each driver is configured to provide a word line voltage. The plurality of sets of word line switches comprise first sets with each first set configured drive to “n” word lines in a different even block of memory cells and second sets with each second set configured to drive “n” word lines in a different odd block of memory cells. The “n” word line switches in each set are numbered in accordance with a physical location of the word lines in the blocks of memory cells. The even and odd blocks are numbered in accordance with physical position of the blocks. Each CGI line is connected between a driver and a word line switch in each set of the word line switches. Each CGI line is connected to a different numbered word line switch in the first sets of word line switches than the second sets of word line switches.

In a further embodiment, the apparatus comprises one or more control circuits in communication with the set of “n” drivers and the plurality of sets of “n” word line switches. The one or more control circuits are configured to select a first set of the first sets of the word line switches and a second set of the second sets of the word line switches that are configured to drive word lines in adjacent even and odd blocks of memory cells. The one or more control circuits are configured to control the drivers and the selected first set and the select second set of word line switches to apply a first voltage to a word line in the even block of the adjacent blocks while applying a second voltage to the same numbered word line in the odd block of the adjacent blocks, wherein the first voltage and the second voltage have different magnitudes.

In a further embodiment, the one or more control circuits are further configured to test for a leakage current between the word line in the even block of the adjacent blocks and the same numbered word line in the odd block of the adjacent blocks responsive to the first voltage and the second voltage.

In an embodiment, the apparatus further comprises one or more control circuits in communication with the set of “n” drivers and the plurality of sets of “n” word line switches. The one or more control circuits configured to select a first set of the first sets of the word line switches and a second set of the second sets of the word line switches that are configured to drive word lines in adjacent even and odd blocks of memory cells. The one or more control circuits configured to control the “n” drivers to provide n/2 first voltages and n/2 second voltages, the first voltages each having a different magnitude than the second voltages. The first voltages each having a different magnitude than the second voltages. The one or more control circuits configured to control the selected first set and the selected second set of word line switches to apply the first voltage to a first n/2 of the word lines in the even block of the adjacent blocks while applying the second voltage to a first n/2 of the word lines in the odd block of the adjacent blocks having the same numbered word lines as the first n/2 word lines in the even block of the adjacent blocks. The one or more control circuits configured to control the first and second sets of word line switches to apply the second voltage to a second n/2 of the word lines in the even block of the adjacent blocks while applying the first voltage to a second n/2 of the word lines in the odd block of the adjacent blocks having the same numbered word lines as the second n/2 word lines in the even block of the adjacent blocks.

In an embodiment of the apparatus, for a plurality of groups of word lines in the even block, the first voltage and the second voltage alternates between adjacent word lines in the group. For a plurality of groups of word lines in the odd block the second voltage and the second voltage and the first voltage alternates between adjacent word lines in the group such that each word line in the odd block receives a different magnitude voltage as its neighbor word line having the same word line number in the even block of the adjacent blocks.

In an embodiment of the apparatus, for a plurality of groups of word lines in the even block of the adjacent blocks, each word line receives either the first voltage or the second voltage. For a plurality of groups of word lines in the odd block of the adjacent blocks, each word line receives either the second voltage or the first voltage such that each word line in the odd block receives a different magnitude voltage as its neighbor word line having the same word line number in the even block.

In an embodiment of the apparatus the word lines in each block comprise a plurality of word line groups with each word line group comprising contiguous word lines in the block, the CGI lines comprise a corresponding plurality of CGI groups, and each group of CGI lines is connected to word line switches in the first sets that provide voltages to word lines in even blocks having a different range of word line numbers than the word lines in odd blocks that are provided voltages by word line switches in the second sets.

In an embodiment of the apparatus a first group of the word line switches are arranged as a first row of word line switch transistors, the first row of word line switch transistors connected to word lines in an even block adjacent to an odd block. A second group of the word line switches are arranged as a second row of word line switch transistors adjacent to the first row of word line switch transistors, the second row of word line switch transistors connected to word lines in the odd block adjacent to the even block. Word line switch transistors in the second row are connected to a word line group that is swapped with a word line group to which adjacent word line switch transistors in the first row are connected.

In an embodiment the apparatus further comprises word line contacts that connect the word line switch transistors to the word lines in the blocks. A pair of the word line contacts that connect to adjacent word line switch transistors in the first row and the second row connect to word lines at different levels in the even block and the odd block.

In an embodiment the apparatus the word line contacts in the even blocks have a first stagger pattern and the word line contacts in the odd blocks have a second stagger pattern that is different from the first stagger pattern.

In an embodiment the apparatus the word line contacts in the even blocks have the same stagger pattern as the word line contacts in the odd blocks.

In an embodiment the apparatus the word line switch transistors for an even block and the word line switch transistors for an adjacent odd block comprise three rows of word line switch transistors, the three rows include a first row, a second row, and a third row. The three rows include a first row, a second row, and a third row. A first group of the word line switch transistors in the first row are connected to a first word line group. A second group of the word line switch transistors in the second row are connected to a second word line group. The same group of CGI lines are connected to both the first group of the word line switch transistors and the second group of the word line switch transistors.

In an embodiment the apparatus the word lines of a block have an internal block address that depends on location of the word line in the block. The apparatus further comprises one or more control circuits in communication with the set of “n” drivers and the plurality of sets of “n” word line switches. The one or more control circuits are configured to provide a word line address and address dependent information to the drivers to cause the drivers to provide a read reference voltage to a different CGI line for even blocks than for odd blocks for the same word line internal block address.

An embodiment includes a method for testing a memory system. The method comprises selecting a first set of word line switches and a second set of word line switches that are configured to drive word lines in a first block of memory cells adjacent to a second block of memory cells; providing a first voltage over a first group of global interconnect (CGI) lines to a first group of word lines switches in the first set and to a second group of word lines switches in the second set; providing a second voltage over a second group of global interconnect (CGI) lines to third group of word lines switches in the first set and to a fourth group of word lines switches in the second set. The first group of word lines switches connect to word lines at the same corresponding physical locations in the first block as the fourth group of word lines switches connect to in the second block. The third group of word lines switches connect to word lines at the same physical locations in the first block as the second group of word lines switches connect to in the second bloc. The method comprises providing the first voltage from the first group of word lines switches while providing the second voltage from the fourth group of word lines switches to the word lines at the same physical locations in the first block and the second block; and providing the second voltage from the third group of word lines switches while providing the first voltage from the second group of word lines switches to the word lines at the same physical locations in the first block and the second block.

An embodiment includes a memory system comprising a memory structure having a plurality of blocks of memory cells, a set of “n” word line drivers, a plurality of sets of “n” word line switches, a set of “n” common global interconnect (CGI) lines coupled between the n drivers and the plurality of sets of “n” word line switches. Each block has a plurality of word lines. Each driver is configured to provide a word line voltage. The plurality of sets of word line switches comprise first sets configured to drive first blocks of memory cells and second sets configured to drive second blocks of memory cells. The “n” word line switches of each set is numbered in accordance with a physical location of the word lines in the blocks of memory cells. Each CGI line is connected between one driver and one word line switch in each set of the word line switches. Each numbered word line switch in the first sets is connected to a different CGI line than the same numbered word line switch in the second sets. The memory system also comprises a control circuit configured to control the word line drivers and the word line switches to provide voltages to the word lines in one or more selected blocks of memory cells.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
a set of “n” drivers, each driver configured to provide a word line voltage;
a plurality of sets of “n” word line switches, the plurality of sets of word line switches comprise first sets with each first set configured drive to “n” word lines in a different even block of memory cells and second sets with each second set configured to drive “n” word lines in a different odd block of memory cells, the “n” word line switches in each set numbered in accordance with a physical location of the word lines in the blocks of memory cells, the even blocks and the odd blocks numbered in accordance with physical position of the blocks; and
a set of “n” common global interconnect (CGI) lines coupled between the “n” drivers and the plurality of sets of “n” word line switches, each CGI line connected between a driver and a word line switch in each set of the word line switches, each CGI line connected to a different numbered word line switch in the first sets of word line switches than the second sets of word line switches.

2. The apparatus of claim 1, further comprising one or more control circuits in communication with the set of “n” drivers and the plurality of sets of “n” word line switches, the one or more control circuits configured to:
select a first set of the first sets of the word line switches and a second set of the second sets of the word line switches that are configured to drive word lines in adjacent even and odd blocks of memory cells; and
control the drivers and the selected first set and the select second set of word line switches to apply a first voltage to a word line in the even block of the adjacent blocks while applying a second voltage to the same numbered word line in the odd block of the adjacent blocks, wherein the first voltage and the second voltage have different magnitudes.

3. The apparatus of claim 2, wherein the one or more control circuits are further configured to:
test for a leakage current between the word line in the even block of the adjacent blocks and the same numbered word line in the odd block of the adjacent blocks responsive to the first voltage and the second voltage.

4. The apparatus of claim 1, further comprising:
one or more control circuits in communication with the set of “n” drivers and the plurality of sets of “n” word line switches, the one or more control circuits configured to:
select a first set of the first sets of the word line switches and a second set of the second sets of the word line switches that are configured to drive word lines in adjacent even and odd blocks of memory cells; and
control the “n” drivers to provide n/2 first voltages and n/2 second voltages, the first voltages each having a different magnitude than the second voltages;
control the selected first set and the selected second set of word line switches to:
apply the first voltage to a first n/2 of the word lines in the even block of the adjacent blocks while applying the second voltage to a first n/2 of the word lines in the odd block of the adjacent blocks having the same numbered word lines as the first n/2 word lines in the even block of the adjacent blocks; and
apply the second voltage to a second n/2 of the word lines in the even block of the adjacent blocks while applying the first voltage to a second n/2 of the word lines in the odd block of the adjacent blocks having the same numbered word lines as the second n/2 word lines in the even block of the adjacent blocks.

5. The apparatus of claim 4, wherein:
for a plurality of groups of word lines in the even block, the first voltage and the second voltage alternates between adjacent word lines in the group; and
for a plurality of groups of word lines in the odd block of the adjacent blocks, the second voltage and the first voltage alternates between adjacent word lines in the group such that each word line in the odd block receives a different magnitude voltage as its neighbor word line having the same word line number in the even block of the adjacent blocks.

6. The apparatus of claim 4, wherein:
for a plurality of groups of word lines in the even block of the adjacent blocks, each word line receives either the first voltage or the second voltage; and
for a plurality of groups of word lines in the odd block of the adjacent blocks, each word line receives either the second voltage or the first voltage such that each word line in the odd block receives a different magnitude voltage as its neighbor word line having the same word line number in the even block.

7. The apparatus of claim 1, wherein:
the word lines in each block comprise a plurality of word line groups with each word line group comprising contiguous word lines in the block;
the CGI lines comprise a corresponding plurality of CGI groups; and
each group of CGI lines is connected to word line switches in the first sets that provide voltages to word lines in even blocks having a different range of word line numbers than the word lines in odd blocks that are provided voltages by word line switches in the second sets.

8. The apparatus of claim 7, wherein:
a first group of the word line switches are arranged as a first row of word line switch transistors, the first row of word line switch transistors connected to word lines in an even block adjacent to an odd block;
a second group of the word line switches are arranged as a second row of word line switch transistors adjacent to the first row of word line switch transistors, the second row of word line switch transistors connected to word lines in the odd block adjacent to the even block; and
word line switch transistors in the second row are connected to a word line group that is swapped with a word line group to which adjacent word line switch transistors in the first row are connected.

9. The apparatus of claim 8, further comprising word line contacts that connect the word line switch transistors to the word lines in the blocks, wherein:
a pair of the word line contacts that connect to adjacent word line switch transistors in the first row and the second row connect to word lines at different levels in the even block and the odd block.

10. The apparatus of claim 9, wherein the word line contacts in the even blocks have a first stagger pattern and the word line contacts in the odd blocks have a second stagger pattern that is different from the first stagger pattern.

11. The apparatus of claim 9, wherein the word line contacts in the even blocks have the same stagger pattern as the word line contacts in the odd blocks.

12. The apparatus of claim 8, wherein:
the word line switch transistors for an even block and the word line switch transistors for an adjacent odd block comprise three rows of word line switch transistors, the three rows include a first row, a second row, and a third row; and
a first group of the word line switch transistors in the first row are connected to a first word line group;
a second group of the word line switch transistors in the second row are connected to a second word line group; and
the same group of CGI lines are connected to both the first group of the word line switch transistors and the second group of the word line switch transistors.

13. The apparatus of claim 1, wherein the word lines of a block have an internal block address that depends on location of the word line in the block, and further comprising:
one or more control circuits in communication with the set of “n” drivers and the plurality of sets of “n” word line switches, the one or more control circuits configured to provide a word line address and address dependent information to the drivers to cause the drivers to provide a read reference voltage to a different CGI line for even blocks than for odd blocks for the same word line internal block address.

14. A method for testing a memory system, the method comprises:
selecting a first set of word line switches and a second set of word line switches that are configured to drive word lines in a first block of memory cells adjacent to a second block of memory cells;
providing a first voltage over a first group of global interconnect (CGI) lines to a first group of word lines switches in the first set and to a second group of word lines switches in the second set;
providing a second voltage over a second group of global interconnect (CGI) lines to third group of word lines switches in the first set and to a fourth group of word lines switches in the second set, the first group of word lines switches connected to word lines at the same corresponding physical locations in the first block as the fourth group of word lines switches are connected to in the second block, the third group of word lines switches connected to word lines at the same physical locations in the first block as the second group of word lines switches are connected to in the second block;
providing the first voltage from the first group of word lines switches while providing the second voltage from the fourth group of word lines switches to the word lines at the same physical locations in the first block and the second block; and
providing the second voltage from the third group of word lines switches while providing the first voltage from the second group of word lines switches to the word lines at the same physical locations in the first block and the second block.

15. The method of claim 14, further comprising:
testing for a leakage current between a first word line in the first block to which the first voltage was applied and a second word line in the second block to which the second voltage was applied.

16. A memory system comprising:
a memory structure having a plurality of blocks of memory cells, each block having a plurality of word lines;
a set of “n” word line drivers, each driver configured to provide a word line voltage;
a plurality of sets of “n” word line switches, the plurality of sets of word line switches comprises first sets configured to drive first blocks of memory cells and second sets configured to drive second blocks of memory cells, the “n” word line switches of each set numbered in accordance with a physical location of the word lines in the blocks of memory cells, each first block adjacent to one of the second blocks;
a set of “n” common global interconnect (CGI) lines coupled between the “n” drivers and the plurality of sets of “n” word line switches, each CGI line connected between one driver and one word line switch in each set of the word line switches, each numbered word line switch in the first sets is connected to a different CGI line than the same numbered word line switch in the second sets; and
a control circuit configured to control the word line drivers and the word line switches to provide voltages to the word lines in one or more selected blocks of memory cells.

17. The memory system of claim 16, wherein the one or more control circuits are configured to:
select a first set of the first sets of the word line switches and a second set of the second sets of the word line switches that are configured to drive word lines in a first block and a second block of memory cells that are adjacent to each other; and
control the drivers and the selected first set and the select second set of word line switches to apply a first voltage to a word line in the first block of the adjacent blocks while applying a second voltage to the same numbered word line in the second block of the adjacent blocks, wherein the first voltage and the second voltage have different magnitudes.

18. The memory system of claim 17, wherein the one or more control circuits are further configured to:
test for a leakage current between the word line in the first block of the adjacent blocks and the same numbered word line in the second block of the adjacent blocks.

19. The memory system of claim 17, wherein the one or more control circuits are further configured to:
select a first set of the first sets of the word line switches and a second set of the second sets of the word line switches that are configured to drive word lines in an adjacent first block and second block of memory cells; and
control the “n” drivers to provide n/2 first voltages and n/2 second voltages, the first voltage each having a different magnitude than the second voltages;
control the selected first set and the selected second set of word line switches to:
apply the first voltage to a first n/2 of the word lines in a first block adjacent to a second block while applying the second voltage to a first n/2 of the word lines in the second block having the same numbered word lines as the first n/2 word lines in the first block; and
apply second voltage to a second n/2 of the word lines in the first block while applying the first voltage to a second n/2 of the word lines in the second block having the same numbered word lines as the second n/2 word lines in the first block.

20. The memory system of claim 16, wherein:
the word lines have an internal block address that depends on the location of the word line within the block; and
the control circuit is configured to provide a word line address and address dependent information to the word line drivers to cause the word line drivers to provide a read reference voltage to a different CGI line for the first blocks than for the second blocks for the same word line address.
